(19) United States
(12) Patent Application Publication
(10) Pub. No.: US 2012/0249740 A1
(43) Pub. Date: Oct. 4, 2012

(54) THREE-DIMENSIONAL IMAGE SENSORS, CAMERAS, AND IMAGING SYSTEMS

(76) Inventors: Tae-Yon LEE, Seoul (KR); Joon-Ho LEE, Seoul (KR); Yoon-Dong PARK, Yongin-si (KR); Kyoung-Ho HA, Seoul (KR); Yong-Jei LEE, Seongnam-si (KR); Kwang-Hyuk BAE, Seoul (KR); Kyu-Min KYUNG, Seoul (KR); Tae-Chan KIM, Yongin-si (KR)

(21) Appl. No.: 13/432,704

(22) Filed: Mar. 28, 2012

(30) Foreign Application Priority Data
Mar. 30, 2011 (KR) 10-2011-0028579
Mar. 31, 2011 (KR) 10-2011-0029249
Mar. 31, 2011 (KR) 10-2011-0029388

(51) Int. Cl. H04N 13/02; H01L 27/146

(52) U.S. Cl. 348/46; 250/208.1; 348/E13.074

(57) ABSTRACT

A three-dimensional image sensor may include a light source module configured to emit at least one light to an object, a sensing circuit configured to polarize a received light that represents the at least one light reflected from the object and configured to convert the polarized light to electrical signals, and a control unit configured to control the light source module and sensing circuit. A camera may include a receiving lens; a sensor module configured to generate depth data, the depth data including depth information of objects based on a received light from the objects; an engine unit configured to generate a depth map of the objects based on the depth data, configured to segment the objects in the depth map, and configured to generate a control signal for controlling the receiving lens based on the segmented objects; and a motor unit configured to control focusing of the receiving lens.

### CROSS-REFERENCE TO RELATED APPLICATION(S)

This application claims priority from Korean Patent Application No. 2011-0028579, filed on Mar. 30, 2011; Korean Patent Application No. 2011-0029249, filed on Mar. 31, 2011; and Korean Patent Application No. 2011-0029388, filed on Mar. 31, 2011; all in the Korean Intellectual Property Office (KIPO), the entire contents of all of which are incorporated herein by reference.

### BACKGROUND

1. Technical Field

Example embodiments relate to image sensors. More particularly, example embodiments relate to three-dimensional image sensors, image pick-up devices, cameras, and imaging systems.

2. Description of the Related Art

An image sensor is a photo-detection device that converts optical signals including image and/or distance (i.e., depth) information about an object into electrical signals. Various types of image sensors, such as charge-coupled device (CCD) image sensors, complimentary metal-oxide-semiconductor (CMOS) image sensors (CISs), etc., have been developed to provide high quality image information about the object. Recently, a three-dimensional (3D) image sensor is being researched and developed which provides depth information as well as two-dimensional image information.

The three-dimensional image sensor may obtain the depth information using infrared light or near-infrared light as a light source.

### SUMMARY

Example embodiments provide a three-dimensional image sensor capable of increasing dynamic ranges.

Example embodiments provide a camera capable of adjusting focusing of a receiving lens.

According to an example embodiment, a three-dimensional image sensor may include a light source module, a sensing circuit, and/or a control unit. The light source module may emit at least one light to an object. The sensing circuit may be configured to polarize a received light that represents the at least one light reflected from the object and configured to convert the polarized light to electrical signals. The control unit may control the light source module and the sensing circuit.

In an example embodiment, the light source module may include a light source configured to generate the at least one light and/or a first lens configured to focus the at least one light on the object.

The sensing circuit may include a lens module and/or a sensor unit. The lens module may include a second lens configured to concentrate the received light; an infrared filter configured to filter visible light components in the received light; and/or a polarization filter configured to polarize an output of the infrared filter in one direction to provide the polarized light. The sensor unit may be configured to convert the polarized light to the electrical signals.

The light source may include a light-emitting diode or a laser diode.

In an example embodiment, the sensing circuit may include a lens module and/or a sensor unit. The lens module may include a second lens configured to concentrate the received light and/or an infrared filter configured to filter visible light components in the received light.

The sensor unit may include a plurality of unit pixels, each of the unit pixels including a grid polarizer. Each unit pixel may include a transmission gate formed over a semiconductor substrate; a floating diffusion region formed over the semiconductor substrate adjacent to the transmission gate; a buried channel formed in the semiconductor substrate adjacent to the transmission gate; a pinning layer formed in the buried channel; and/or a metal layer formed over the transmission gate and the buried channel. The grid polarizer may be configured to polarize an output of the infrared filter. The grid polarizer may include the buried channel and the metal layer.

In an example embodiment, the at least one light may include first and second lights. The light source module may include a first light source configured to emit the first light and/or a second light source configured to emit the second light. The sensing circuit may include a lens configured to concentrate the received light.

The first and second light sources may be opposed to each other with respect to the lens.

The first and second lights may have a same period with respect to each other. The control unit may provide first and second control signals that alternately enable the first and second light sources.

According to an example embodiment, a camera may include receiving lens, a sensor module, an engine unit, and/or a motor unit. The sensor module may be configured to generate depth data, the depth data including depth information of a plurality of objects based on a received light from the objects. The engine unit may be configured to generate a depth map of the objects based on the depth data, may be configured to segment the objects in the depth map based on the depth map, and/or may be configured to generate a control signal for controlling the receiving lens based on the segmented objects. The motor unit may be configured to control focusing of the receiving lens. The sensor module may be configured to generate color data of the objects based on visible light reflected from the objects and concentrated by the receiving lens. The motor unit may be configured to control focusing of the receiving lens to provide the color data to the engine unit.

The sensor module may include a depth sensor configured to generate the depth data; and/or a color sensor configured to generate the color data.

The engine unit may include a first image signal processor (ISP) configured to process the depth data to generate a depth image of the objects and the depth map; a segmentation and control unit configured to segment the objects based on the depth map, and configured to generate the control signal based on the segmented objects; and/or a second ISP configured to process the color data to generate a color image of the objects.

The second ISP may be configured to perform color image processing on each of the objects according to respective distances of the objects from the sensor module.

The receiving lens may be configured to have a depth of field that covers one of the objects.

The camera may further include an image generator. The image generator may be configured to execute an application to generate a stereo image of the objects based on the depth image and the color image.

An imaging system may include a receiving lens; a sensor module configured to generate color data and depth data, the color data including color information of one or more objects based on received light from the one or more objects, and the depth data including depth information of the one or more objects based on the received light from the objects; an engine unit configured to generate a color image of the one or more objects based on the color data, configured to generate a depth image of the one or more objects based on the depth data, configured to generate a depth map of the one or more objects based on the depth data, and/or configured to generate a control signal for controlling the receiving lens based on the depth map; and/or a motor unit configured to control focusing of the receiving lens based on the control signal.

The sensor module may be further configured to generate the color data based on visible light reflected from the one or more objects and concentrated by the receiving lens.

The sensor module may be further configured to generate the depth data based on infrared or near-infrared light reflected from the one or more objects and concentrated by the receiving lens.

The sensor module may be further configured to polarize light reflected from the one or more objects.

The sensor module may be further configured to configured to convert the polarized light to electrical signals.

As described above, dynamic ranges of a three-dimensional image sensor may be increased and focusing of a receiving lens of a camera may be adaptively adjusted.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIG. 1 is a block diagram illustrating a three-dimensional image sensor according to an example embodiment;

FIG. 2 is a diagram for describing an example of calculating a distance of an object by a three-dimensional image sensor of FIG. 1;

FIG. 3 illustrates an example of the light source module in FIG. 1 according to the example embodiment;

FIG. 4 illustrates another example of the light source module in FIG. 1 according to another example embodiment;

FIG. 5 is a flow chart illustrating a method of operating a three-dimensional image sensor according to these example embodiments;

FIG. 6 is a flow chart illustrating another method of operating a three-dimensional image sensor according to these example embodiments;

FIG. 7 is a block diagram illustrating another three-dimensional image sensor according to yet another example embodiment;

FIG. 8 illustrates a cross-sectional view of a unit pixel included in a pixel array according to the yet another example embodiment;

FIG. 9 illustrates top view of a part of the unit pixel of FIG. 8;

FIG. 10 illustrates a three-dimensional image sensor system according to still another example embodiment;

FIG. 11 is a block diagram illustrating a three-dimensional image sensor according to the still another example embodiment;

FIG. 12 illustrates relative positions of the light sources and the light-receiving lens in FIG. 11;

FIG. 13 illustrates the control signals and the emitted lights in FIG. 11;

FIG. 14 illustrates the emitted lights and the received light in FIG. 11;

FIG. 15 is a diagram for describing an example of calculating a distance of an object by a three-dimensional image sensor of FIG. 11;

FIG. 16 is a flow chart illustrating an example of a method of measuring a distance of an object by a three-dimensional image sensor according to the still another example embodiment;

FIG. 17 is a flow chart illustrating another example of a method of measuring a distance of an object by a three-dimensional image sensor according to the still another example embodiment;

FIG. 18 is a diagram illustrating an example of a sensor unit of a three-dimensional image sensor according to the still another example embodiment;

FIG. 19 is a block diagram illustrating an example of a camera including a three-dimensional image sensor according to a further example embodiment;

FIG. 20 is a block diagram illustrating an example of a camera including a three-dimensional image sensor according to yet a further example embodiment;

FIG. 21 is a block diagram illustrating a camera including a three-dimensional image sensor according to an even further example embodiment;

FIG. 22 is a block diagram illustrating an example of the three-dimensional image sensor chip in FIG. 21 according to the even further example embodiment;

FIG. 23 is a block diagram illustrating an example of depth sensor in FIG. 22 according to the even further example embodiment;

FIG. 24 is a block diagram illustrating another example of the three-dimensional image sensor chip in FIG. 21 according to the even further example embodiment;

FIG. 25 is a block diagram illustrating an engine unit in FIG. 21 according to the even further example embodiment;

FIG. 26 is a block diagram illustrating the host/application in FIG. 21 according to the even further example embodiment;

FIG. 27 illustrates depth map of a plurality of objects according to an example embodiment;

FIGS. 28A through 28C respectively illustrate a selected object in the depth map of FIG. 27 according to the example embodiment;

FIGS. 29A through 29C respectively illustrate a color image focused on the respective selected object in FIGS. 28A through 28C according to the example embodiment;

FIG. 30 is a block diagram illustrating a camera including a three-dimensional image sensor according to a still further example embodiment;

FIG. 31 is a block diagram illustrating an engine unit in FIG. 30 according to the still further example embodiment;

FIG. 32 is a block diagram illustrating the host/application in FIG. 30 according to the still further example embodiment;

FIG. 33 illustrates a color image of a plurality of objects according to an example embodiment;

FIG. 34 illustrates depth map of a plurality of objects according to the example embodiment;

FIGS. 35A through 35C respectively illustrate a blurred color image of the respective selected object according to the example embodiment;

FIG. 36 is a flow chart illustrating an example of a method of processing image according to an example embodiment;

FIG. 37 is a flow chart illustrating another example of a method of processing image according to another example embodiment;

FIG. 38 is a block diagram illustrating a computing system including a camera according to a further example embodiment; and

FIG. 39 is a block diagram illustrating an example of an interface used in a computing system of FIG. 38.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

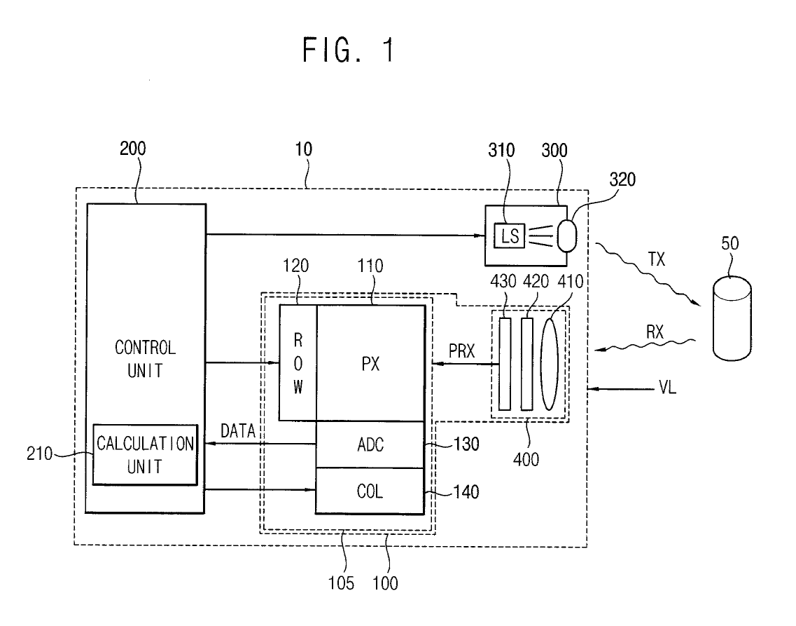

FIG. 1 is a block diagram illustrating a three-dimensional image sensor according to an example embodiment.

Referring to FIG. 1, a three-dimensional image sensor 10 includes sensing circuit 100 including a sensor unit 105 and lens module 400, a control unit 200 and a light source module 300. The sensor unit 105 includes a pixel array 110, an analog-to-digital conversion (ADC) unit 130, a row scanning circuit 120 and a column scanning circuit 140.

The pixel array 110 may include depth pixels receiving received light RX that is emitted by the light source module 300, is reflected from an object 50, and is received as received light RX. The depth pixels may convert the received light RX into electrical signals. The depth pixels may provide information about a distance of the object 50 from the three-dimensional image sensor 10 and/or black-and-white image information.

The pixel array 110 may further include color pixels for providing color image information. In this case, the three-dimensional image sensor 10 may be a three-dimensional color image sensor that provides the color image information and the depth information. In some embodiments, an infrared filter or a near-infrared filter may be formed on the depth pixels, and a color filter (e.g., red, green and blue filters) may be formed on the color pixels. A ratio of the number of the depth pixels to the number of the color pixels may vary according to example embodiments.

The ADC unit 130 may convert an analog signal output from the pixel array 110 into a digital signal. In some embodiments, the ADC unit 130 may perform a column ADC that converts analog signals in parallel using a plurality of analog-to-digital converters respectively coupled to a plurality of column lines. In other embodiments, the ADC unit 130 may perform a single ADC that sequentially converts the analog signals using a single analog-to-digital converter.

In some embodiments, the ADC unit 130 may further include a correlated double sampling (CDS) unit for extracting an effective signal component. In some embodiments, the CDS unit may perform an analog double sampling that extracts the effective signal component based on a difference between an analog reset signal including a reset component and an analog data signal including a signal component. In other embodiments, the CDS unit may perform a digital double sampling that converts the analog reset signal and the analog data signal into two digital signals and extracts the effective signal component based on a difference between the two digital signals. In still other embodiments, the CDS unit may perform a dual correlated double sampling that performs both the analog double sampling and the digital double sampling.

The row scanning circuit 120 may receive control signals from the control unit 200, and may control a row address and a row scan of the pixel array 110. To select a row line among a plurality of row lines, the row scanning circuit 120 may apply a signal for activating the selected row line to the pixel array 110. In some embodiments, the row scanning circuit 120 may include a row decoder that selects a row line of the pixel array 110 and a row driver that applies a signal for activating the selected row line.

The column scanning circuit 140 may receive control signals from the control unit 200, and may control a column address and a column scan of the pixel array 110. The column scanning circuit 140 may output a digital output signal from the ADC unit 130 to a digital signal processing circuit (not shown) or to an external host (not shown). For example, the column scanning circuit 140 may provide the ADC unit 130 with a horizontal scan control signal to sequentially select a plurality of analog-to-digital converters included in the ADC unit 130. In some embodiments, the column scanning circuit 140 may include a column decoder that selects one of the plurality of analog-to-digital converters and a column driver that applies an output of the selected analog-to-digital converter to a horizontal transmission line. The horizontal transmission line may have a bit width corresponding to that of the digital output signal.

The control unit 200 may control the ADC unit 130, the row scanning circuit 120, the column scanning circuit 140 and the light source module 300. The control unit 200 may provide the ADC unit 130, the row scanning circuit 120, the column scanning circuit 140 and the light source module 300 with control signals, such as a clock signal, a timing control signal, etc. In some embodiments, the control unit 200 may include a control logic circuit, a phase locked loop circuit, a timing control circuit, a communication interface circuit, etc.

The light source module 300 may emit light of a desired (or, alternatively, a predetermined) wavelength. For example, the light source module 300 may emit infrared light or near-infrared light. The light source module 300 may include a light source 310 and a lens 320. The light source 310 may be controlled by the control unit 200 to emit the emitted light TX of which the intensity periodically changes. For example, the intensity of the emitted light TX may be controlled such that the intensity of the emitted light TX has a waveform of a pulse wave, a sine wave, a cosine wave, etc. The light source 310 may be implemented by a light emitting diode (LED), a laser diode, etc. The lens 320 may be configured to focus the emitted light TX on the object 50.

The lens module 400 may include a lens 410, a first filter 420 and a second filter 430. The lens 410 concentrates the received light RX reflected from the object 50 to be provided to the pixel array 110. The first filter 420 may be an infrared filter which filters components having frequencies other than a frequency corresponding to an infrared light, such as visible light VL. The second filter 430 may be a polarization filter which filters background lights other than the emitted light TX. The second filter 430 may be a linear polarization filter and the background lights are polarized in all directions. When the linear polarization filter which is polarized in one direction is employed as the second filter 430, components of the background lights may be reduced by ½. That is, the lens module 400 may polarize the received light RX in one direction to provide the polarized light PRX to the sensor unit 105. The sensor unit 105 may convert the polarized light PRX to electrical signals.

Hereinafter, an operation of the three-dimensional image sensor 10 according to example embodiments will be described below.

The control unit 200 may control the light source module 300 to emit the emitted light TX having the periodic intensity. The emitted light TX emitted by the light source module 300 may be reflected from the object 50 back to the three-dimensional image sensor 10 as the received light RX. The received light RX may enter the depth pixels, and the depth pixels may be activated by the row scanning circuit 120 to output analog signals corresponding to the received light RX. The ADC unit 130 may convert the analog signals output from the depth pixels into digital data DATA. The digital data DATA may be provided to the control unit 200 by the column scanning circuit 140.

A calculation unit 210 included in the control unit 200 may calculate a distance of the object 50 from the three-dimensional image sensor 10 based on the digital data DATA.

The emitted light TX emitted by the light source module 300 may be reflected from the object 50 back to the three-dimensional image sensor 10 as the received light RX. The polarized light PRX may enter the depth pixels, the depth pixels may output analog signals corresponding to the polarized light PRX, and the ADC unit 130 may convert the analog signals output from the depth pixels into digital data DATA. The digital data DATA may be converted to the depth information by the calculation unit 210.

The digital data DATA and/or the depth information may be provided to the digital signal processing circuit or the external host. In some embodiments, the pixel array 110 may include color pixels, and the color image information as well as the depth information may be provided to the digital signal processing circuit or the external host.

As described above, in the three-dimensional image sensor 10 according to example embodiments, since the lens module 400 including the second filter 430 (that may be a polarization filter) polarizes the received light RX in one direction and provides the polarized light PRX to the sensor unit 105, the interference effect due to the background lights may be reduced and a dynamic range of the three-dimensional image sensor 10 may be enhanced.

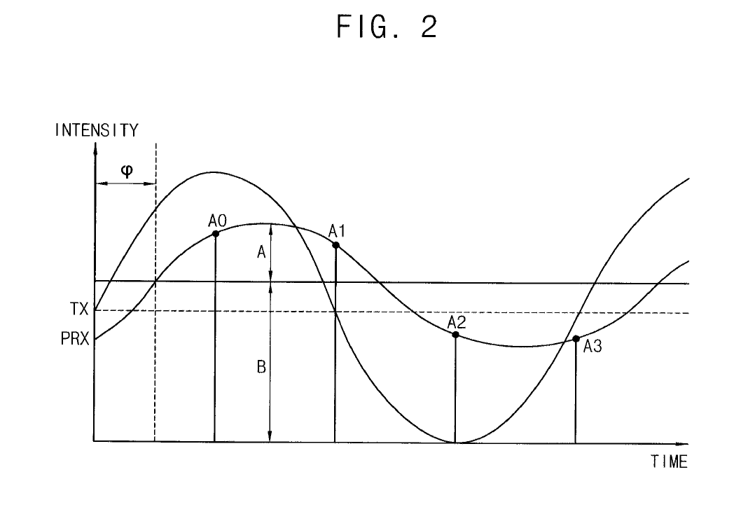

FIG. 2 is a diagram for describing an example of calculating a distance of an object by a three-dimensional image sensor of FIG. 1.

Referring to FIGS. 1 and 2, emitted light TX emitted by a light source module 300 may have a periodic intensity. For example, the intensity (i.e., the number of photons per unit area) of the emitted light TX may have a waveform of a sine wave.

The emitted light TX emitted by the light source module 300 may be reflected from the object 50, and then may enter a lens module 400 as received light RX. The lens module 400 including the second filter 430 (that may be a polarization filter) polarizes the received light RX in one direction and provides the polarized light PRX to the sensor unit 105. The pixel array 110 may periodically sample the polarized light PRX. In some embodiments, during each period of the received light RX (i.e., period of the emitted light TX), the pixel array 110 may perform a sampling on the polarized light PRX with two sampling points having a phase difference of about 180 degrees, with four sampling points having a phase difference of about 90 degrees, or with more than four sampling points. For example, the pixel array 110 may extract four samples A0, A1, A2 and A3 of the polarized light PRX (or, in general, received light RX) at phases of about 90 degrees, about 180 degrees, about 270 degrees and about 360 degrees per period, respectively.

The polarized light PRX may have an offset B that is different from an offset of the emitted light TX emitted by the light source module 300 due to background light, a noise, etc. The offset B of the polarized light PRX may be calculated by Equation 1.

$$B = \frac{A 0 + A 1 + A 2 + A 3}{4} \qquad [ Equation 1 ]$$

Here, A0 represents an intensity of the polarized light PRX sampled at a phase of about 90 degrees of the emitted light TX, A1 represents an intensity of the polarized light PRX sampled at a phase of about 180 degrees of the emitted light TX, A2 represents an intensity of the polarized light PRX sampled at a phase of about 270 degrees of the emitted light TX, and A3 represents an intensity of the polarized light PRX sampled at a phase of about 360 degrees of the emitted light TX.

The polarized light PRX may have an amplitude A lower than that of the emitted light TX emitted by the light source module 300 due to a light loss. The amplitude A of the polarized light PRX may be calculated by Equation 2.

$$A = \frac{\sqrt{{( A 0 - A 2 )}^{2} + {( A 1 - A 3 )}^{2}}}{2} \qquad [ Equation 2 ]$$

Black-and-white image information about the object 50 may be provided by respective depth pixels included in the pixel array 110 based on the amplitude A of the polarized light PRX.

The polarized light PRX may be delayed by a phase difference Φ corresponding to a double of the distance of the object 50 from the three-dimensional image sensor 10 with respect to the emitted light TX. The phase difference Φ between the emitted light TX and the polarized light PRX may be calculated by Equation 3.

$$ϕ = {tan}^{- 1} \frac{{A}_{3} - {A}_{1}}{{A}_{0} - {A}_{2}} \qquad [ Equation 3 ]$$

The phase difference Φ between the emitted light TX and the polarized light PRX may correspond to a time-of-flight (TOF). The distance of the object 50 from the three-dimensional image sensor 10 may be calculated by an equation, “R=c*TOF/2”, where R represents the distance of the object 50, and c represents the speed of light. Further, the distance of the object 50 from the three-dimensional image sensor 50 may also be calculated by Equation 4 using the phase difference Φ between the emitted light TX and the polarized light PRX.

$$R = \frac{c}{4 π f} φ \qquad [ Equation 4 ]$$

Here, f represents a modulation frequency, which is a frequency of the intensity of the emitted light TX (or a frequency of the intensity of the received light RX).

As described above, the three-dimensional image sensor 10 according to example embodiments may obtain depth information about the object 50 using the emitted light TX emitted by the light source module 300. Although FIG. 2 illustrates the emitted light TX of which the intensity is modulated to have a waveform of a sine wave, the three-dimensional image sensor 10 may use the emitted light TX of which the intensity is modulated to have various types of waveforms according to example embodiments. Further, the three-dimensional image sensor 10 may extract the depth information in various manners according to the waveform of the intensity of the emitted light TX, a structure of a depth pixel, etc.

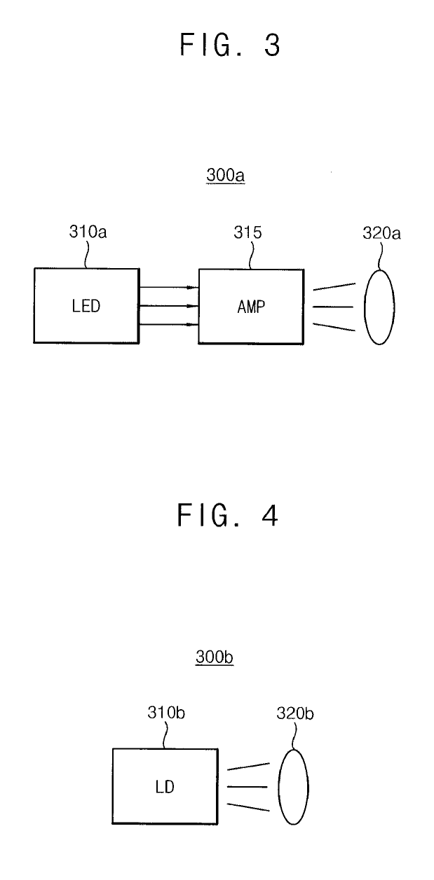

FIG. 3 illustrates an example of the light source module in FIG. 1 according to the example embodiment.

Referring to FIG. 3, a light source module 300a may include a light source 310a which is implemented with a light emitting diode (LED), an amplifier 315 and a lens 320a. When the light source 310a is implemented with an LED, light output from the light source 310a has components polarized in all directions. Therefore, when the received light RX passes through the second filter 430 (that may be a polarization filter) in the lens module 400, intensity of the polarized light PRX may be reduced by ½. Accordingly, when the light source 310a is implemented with an LED, the amplifier 315 amplifies the light from the light source 310a for compensating for reduction of the intensity of the received light RX in the second filter 430 (that may be a polarization filter). That is, the amplifier 315 may increase the intensity of the emitted light TX by two times in the light source module 300a.

FIG. 4 illustrates another example of the light source module in FIG. 1 according to another example embodiment.

Referring to FIG. 4, a light source module 300b may include a light source 310b which is implemented with a laser diode (LD) and a lens 320b. When the light source 310b is implemented with a LD, light output from the light source 310b has components polarized in one direction. Therefore, when the received light RX passes through the second filter 430 (that may be a polarization filter) in the lens module 400, intensity of the polarized light PRX may not be reduced, because the second filter 430 (that may be a polarization filter) in the lens module 400 polarizes the received light RX in a same direction as a polarized direction of the emitted light TX.

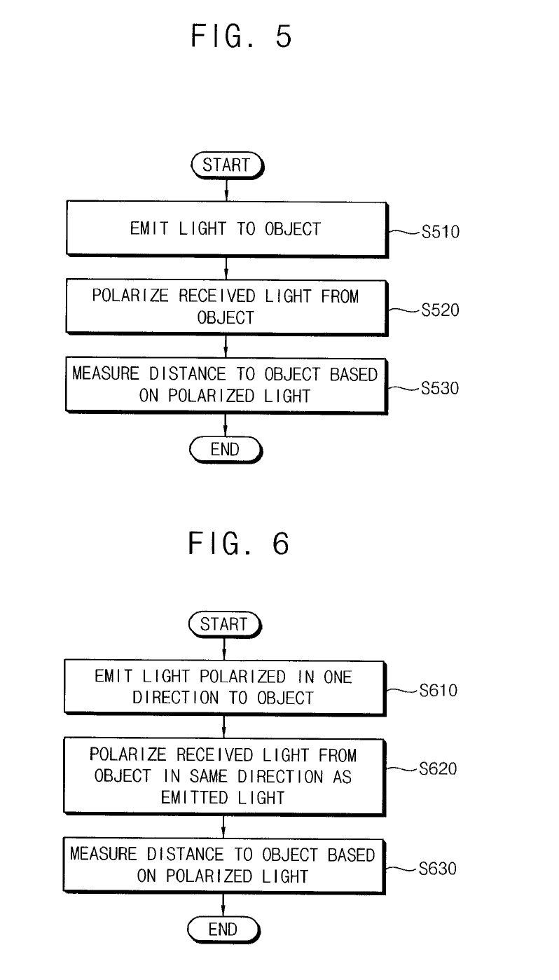

FIG. 5 is a flow chart illustrating a method of operating a three-dimensional image sensor according to these example embodiments.

Referring to FIGS. 1, 3, 4 and 5, a three-dimensional image sensor 10 emits an emitted light TX to an object (S510). A received light RX, the emitted light TX that is reflected from the object 50, is polarized by a second filter 430 (that may be a polarization filter) in a lens module 400 (S520). A sensor unit 105 measures distance of the object 50 from the three-dimensional image sensor 10 based on the polarized light PRX (S530). In some embodiments, the light source module 300 may include the amplifier 315 which increases intensity of the emitted light TX for preventing the intensity of the polarized light PRX from being decreased.

FIG. 6 is a flow chart illustrating another method of operating a three-dimensional image sensor according to these example embodiments.

Referring to FIGS. 1, 3, 4 and 6, a three-dimensional image sensor 10 emits an emitted light TX polarized in one direction to an object (S610). A received light RX, the emitted light TX that is reflected from the object 50, is polarized in a same direction as the emitted light TX is polarized by a second filter 430 (that may be a polarization filter) in a lens module 400 (S620). A sensor unit 105 measures distance of the object 50 from the three-dimensional image sensor 10 based on the polarized light PRX (S630). In some embodiments, the light source module 300 may include a laser diode 310b which emits the emitted light TX polarized in one direction.

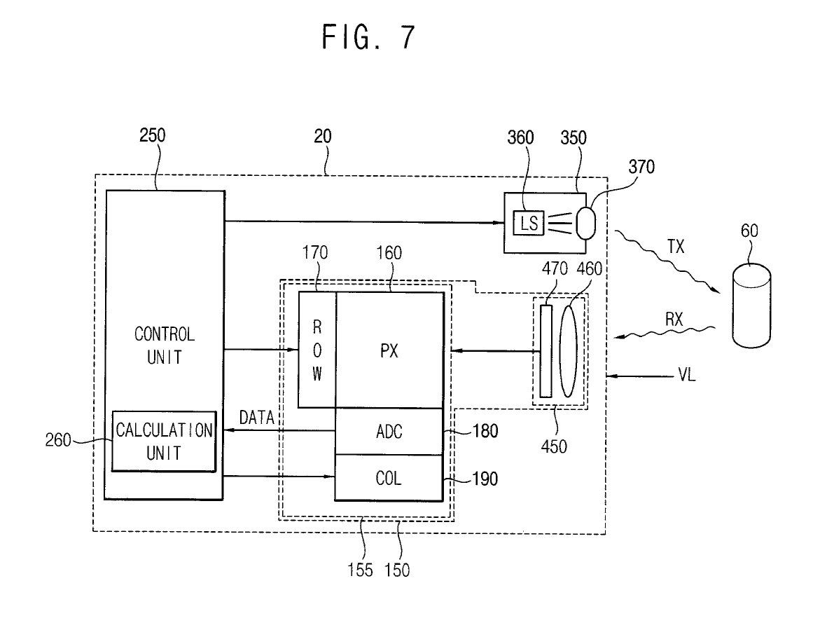

FIG. 7 is a block diagram illustrating another three-dimensional image sensor according to yet another example embodiment.

Referring to FIG. 7, a three-dimensional image sensor 20 includes sensing circuit 150 including a sensor unit 155 and lens module 450, a control unit 250 and a light source module 350. The sensor unit 155 includes a pixel array 160, an analog-to-digital conversion (ADC) unit 180, a row scanning circuit 170 and a column scanning circuit 190.

The pixel array 160 may include depth pixels receiving received light RX that is emitted by the light source module 350 and is reflected from an object 60. The depth pixels may convert the received light RX into electrical signals. The depth pixels may provide information about a distance of the object 60 from the three-dimensional image sensor 20 and/or black-and-white image information.

The pixel array 160 may further include color pixels for providing color image information. In this case, the three-dimensional image sensor 20 may be a three-dimensional color image sensor that provides the color image information and the depth information. In some embodiments, an infrared filter or a near-infrared filter may be formed on the depth pixels, and a color filter (e.g., red, green and blue filters) may be formed on the color pixels. A ratio of the number of the depth pixels to the number of the color pixels may vary according to example embodiments.

The ADC unit 180 may convert an analog signal output from the pixel array 160 into a digital signal. In some embodiments, the ADC unit 180 may perform a column ADC that converts analog signals in parallel using a plurality of analog-to-digital converters respectively coupled to a plurality of column lines. In other embodiments, the ADC unit 180 may perform a single ADC that sequentially converts the analog signals using a single analog-to-digital converter.

In some embodiments, the ADC unit 180 may further include a correlated double sampling (CDS) unit for extracting an effective signal component. In some embodiments, the CDS unit may perform an analog double sampling that extracts the effective signal component based on a difference between an analog reset signal including a reset component and an analog data signal including a signal component. In other embodiments, the CDS unit may perform a digital double sampling that converts the analog reset signal and the analog data signal into two digital signals and extracts the effective signal component based on a difference between the two digital signals. In still other embodiments, the CDS unit may perform a dual correlated double sampling that performs both the analog double sampling and the digital double sampling.

The row scanning circuit 170 may receive control signals from the control unit 250, and may control a row address and a row scan of the pixel array 160. To select a row line among a plurality of row lines, the row scanning circuit 170 may apply a signal for activating the selected row line to the pixel array 160. In some embodiments, the row scanning circuit 170 may include a row decoder that selects a row line of the pixel array 160 and a row driver that applies a signal for activating the selected row line.

The column scanning circuit 190 may receive control signals from the control unit 250, and may control a column address and a column scan of the pixel array 160. The column scanning circuit 190 may output a digital output signal from the ADC unit 180 to a digital signal processing circuit (not shown) or to an external host (not shown). For example, the column scanning circuit 190 may provide the ADC unit 180 with a horizontal scan control signal to sequentially select a plurality of analog-to-digital converters included in the ADC unit 180. In some embodiments, the column scanning circuit 190 may include a column decoder that selects one of the plurality of analog-to-digital converters and a column driver that applies an output of the selected analog-to-digital converter to a horizontal transmission line. The horizontal transmission line may have a bit width corresponding to that of the digital output signal.

The control unit 250 may control the ADC unit 180, the row scanning circuit 170, the column scanning circuit 190 and the light source module 350. The control unit 250 may provide the ADC unit 180, the row scanning circuit 170, the column scanning circuit 190 and the light source module 350 with control signals, such as a clock signal, a timing control signal, etc. In some embodiments, the control unit 250 may include a control logic circuit, a phase locked loop circuit, a timing control circuit, a communication interface circuit, etc.

The light source module 350 may emit light of a desired (or, alternatively, a predetermined) wavelength. For example, the light source module 350 may emit infrared light or near-infrared light. The light source module 350 may include a light source 360 and a lens 370. The light source 360 may be controlled by the control unit 250 to emit the emitted light TX of which the intensity periodically changes. For example, the intensity of the emitted light TX may be controlled such that the intensity of the emitted light TX has a waveform of a pulse wave, a sine wave, a cosine wave, etc. The light source 360 may be implemented by a light emitting diode (LED), a laser diode, etc. The lens 370 may be configured to focus the emitted light TX on the object 60.

The lens module 450 may include a lens 460 and an infrared filter 470. The lens 460 concentrates the received light RX reflected from the object 60 to be provided to the pixel array 160. The infrared filter 470 filters components having frequencies other than a frequency corresponding to an infrared light, such as visible light VL.

The sensor unit 155 polarizes the received light RX which passes through the lens module 450 and converts the polarized light to electrical signals. For polarizing the received light RX and converting the polarized light to electrical signals, the pixel array 160 may include a plurality of pixels, each including a polarization grid as will be described below. That is, the three-dimensional image sensor 20 of FIG. 7 has a polarization function in the pixel array 160.

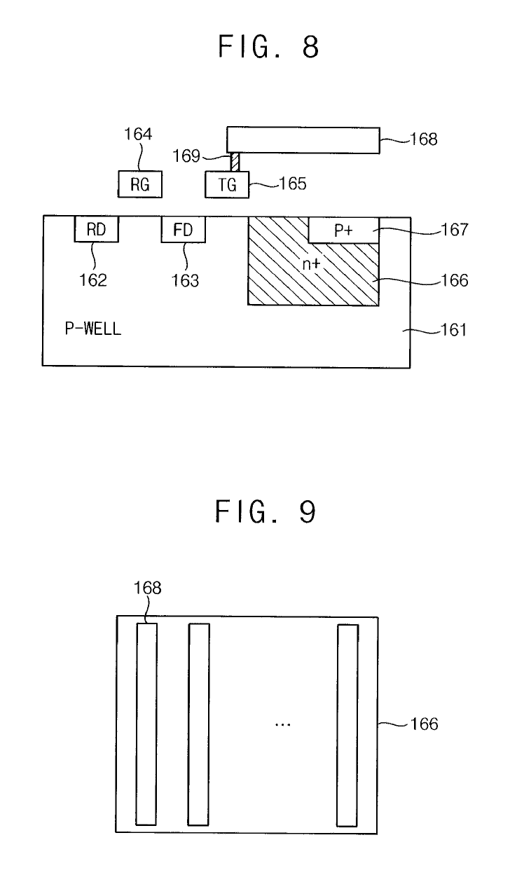

FIG. 8 illustrates a cross-sectional view of a unit pixel included in the pixel array 160 according to the yet another example embodiment.

Referring to FIG. 8, a unit pixel may include a drain region 162, a floating diffusion region 163, a buried channel 166 and a pinning layer 167 which are formed in a p-type semiconductor substrate (P-WELL) 161. The unit pixel may further include a reset transistor 164, a transmission gate 165 and a metal layer 168. The reset transistor 164 may be formed over the semiconductor substrate 161 adjacent to the drain region 162 and the floating diffusion region 163. The transmission gate 165 may be formed over the semiconductor substrate 161 adjacent to the floating diffusion region 163 and the buried channel 166. The metal layer 168 may be formed over the transmission gate 165 and the buried channel 166. The pinning layer 167 may be formed in the buried channel 166, and the transmission gate and the metal layer 168 may be connected with each other through a contact 169. The drain region 162 and the floating diffusion region 163 may be doped with n-type impurity, the buried channel 166 may be more lightly doped with n-type impurity than the floating diffusion region 163, and the pinning layer 167 may be doped with p-type impurity. The buried channel 166 may operate as a photo diode, and the buried layer 166 and the metal layer 168 may constitute a grid polarizer to polarize the received light RX in one direction.

FIG. 9 illustrates top view of a part of the unit pixel of FIG. 8.

Referring to FIG. 9, it is noted that the metal layer 168 is spaced apart with a regular interval over the buried channel which operates as a photo diode.

Hereinafter, an operation of the three-dimensional image sensor 20 according to example embodiments will be described below.

The control unit 250 may control the light source module 350 to emit the emitted light TX having the periodic intensity. The emitted light TX emitted by the light source module 350 may be reflected from the object 60 back to the three-dimensional image sensor 20 as the received light RX. The received light RX may enter the depth pixels after only the infrared components pass through the lens module 450. The depth pixels may polarize the received light in one direction, and the depth pixels may be activated by the row scanning circuit 170 to output analog signals corresponding to the received light RX. The ADC unit 180 may convert the analog signals output from the depth pixels into digital data DATA. The digital data DATA may be provided to the control unit 250 by the column scanning circuit 190.

A calculation unit 260 included in the control unit 250 may calculate a distance of the object 60 from the three-dimensional image sensor 20 based on the digital data DATA.

The emitted light TX emitted by the light source module 350 may be reflected from the object 60 back to the three-dimensional image sensor 20 as the received light RX. The received light RX may enter the depth pixels. The depth pixels may polarize the received light RX, output analog signals corresponding to the received light RX, and the ADC unit 180 may convert the analog signals output from the depth pixels into digital data DATA. The digital data DATA may be converted to the depth information by the calculation unit 260.

The digital data DATA and/or the depth information may be provided to the digital signal processing circuit or the external host. In some embodiments, the pixel array 160 may include color pixels, and the color image information as well as the depth information may be provided to the digital signal processing circuit or the external host.

As described above, in the three-dimensional image sensor 20 according to example embodiments, since the pixel array 160 including the grid polarizer of FIG. 9 polarizes the received light RX in one direction, the interference effect due to the background lights may be reduced and a dynamic range of the three-dimensional image sensor 20 may be enhanced.

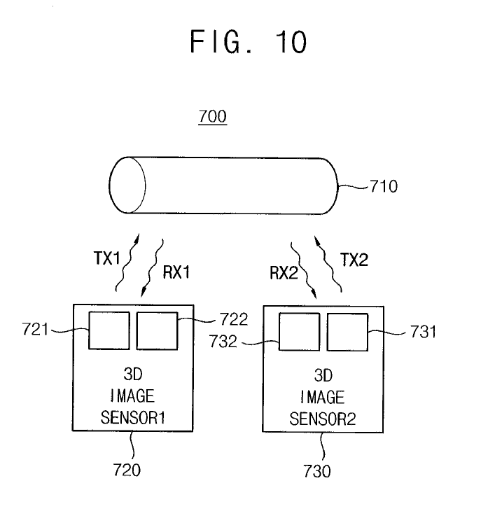

FIG. 10 illustrates a three-dimensional image sensor system according to still another example embodiment.

Referring to FIG. 10, a three-dimensional image sensor system 700 may include an object 710 and first and second three-dimensional image sensors 720 and 730.

The first three-dimensional image sensor 720 may include a light source module 721 and a lens module 722. The second three-dimensional image sensor 730 may include a light source module 731 and a lens module 732. In addition, each of the first and second image sensors may further include a sensing circuit and a control unit such as the three-dimensional image sensors 10 and 20 of FIGS. 1 and 7.

The light source module 721 of the first three-dimensional image sensor 720 emits an emitted light TX1 polarized in a first direction, and the lens module 722 of the first three-dimensional image sensor 720 may include a polarization filter to polarize a received light RX1 from the object 710 in one direction and may convert a polarized light to electrical signals. The light source module 731 of the second three-dimensional image sensor 730 emits an emitted light TX2 polarized in a second direction, and the lens module 732 of the first three-dimensional image sensor 720 may include a polarization filter to polarize a received light RX2 from the object 710 in one direction and may convert a polarized light to electrical signals. The first direction may differ from the second direction.

As described above, in the three-dimensional image sensor system 700 according to example embodiments, since the light source module 721 emits emitted light TX1 polarized in the first direction while the light source module 731 emits emitted light TX2 polarized in the second direction different from the first direction, the interference effect due to a plurality of emitted lights may be reduced and a dynamic range of the three-dimensional image sensor system 700 may be enhanced.

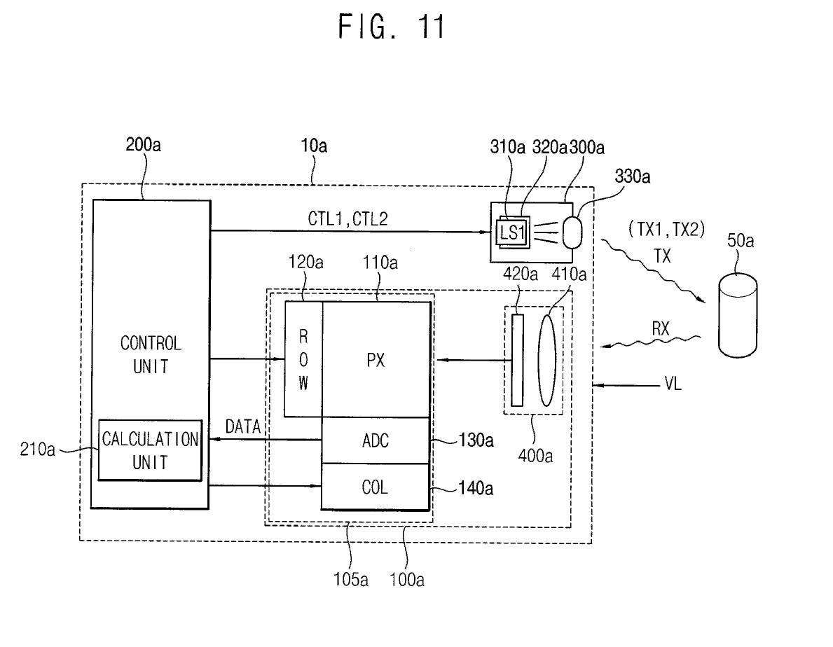

FIG. 11 is a block diagram illustrating a three-dimensional image sensor according to the still another example embodiment.

Referring to FIG. 11, a three-dimensional image sensor 10a includes sensing circuit 100a including a sensor unit 105a and lens module 400a, a control unit 200a and a light source module 300a. The sensor unit 105a includes a pixel array 110a, an analog-to-digital conversion (ADC) unit 130a, a row scanning circuit 120a and a column scanning circuit 140a.

The pixel array 110a may include depth pixels receiving light RX that a first emitted light TX1 and a second emitted light TX2 is emitted by the light source module 350 and is reflected from an object 50a. The depth pixels may convert the received light RX into electrical signals. The depth pixels may provide information about a distance of the object 50a from the three-dimensional image sensor 10a and/or black-and-white image information.

The pixel array 110a may further include color pixels for providing color image information. In this case, the three-dimensional image sensor 10a may be a three-dimensional color image sensor that provides the color image information and the depth information. In some embodiments, an infrared filter or a near-infrared filter may be formed on the depth pixels, and a color filter (e.g., red, green and blue filters) may be formed on the color pixels. A ratio of the number of the depth pixels to the number of the color pixels may vary according to example embodiments.

The ADC unit 130a may convert an analog signal output from the pixel array 110a into a digital signal. In some embodiments, the ADC unit 130a may perform a column ADC that converts analog signals in parallel using a plurality of analog-to-digital converters respectively coupled to a plurality of column lines. In other embodiments, the ADC unit 130a may perform a single ADC that sequentially converts the analog signals using a single analog-to-digital converter.

In some embodiments, the ADC unit 130a may further include a correlated double sampling (CDS) unit for extracting an effective signal component. In some embodiments, the CDS unit may perform an analog double sampling that extracts the effective signal component based on a difference between an analog reset signal including a reset component and an analog data signal including a signal component. In other embodiments, the CDS unit may perform a digital double sampling that converts the analog reset signal and the analog data signal into two digital signals and extracts the effective signal component based on a difference between the two digital signals. In still other embodiments, the CDS unit may perform a dual correlated double sampling that performs both the analog double sampling and the digital double sampling.

The row scanning circuit 120a may receive control signals from the control unit 200a, and may control a row address and a row scan of the pixel array 110a. To select a row line among a plurality of row lines, the row scanning circuit 120a may apply a signal for activating the selected row line to the pixel array 110a. In some embodiments, the row scanning circuit 120a may include a row decoder that selects a row line of the pixel array 110a and a row driver that applies a signal for activating the selected row line.

The column scanning circuit 140a may receive control signals from the control unit 200a, and may control a column address and a column scan of the pixel array 110a. The column scanning circuit 140a may output a digital output signal from the ADC unit 130a to a digital signal processing circuit (not shown) or to an external host (not shown). For example, the column scanning circuit 140a may provide the ADC unit 130a with a horizontal scan control signal to sequentially select a plurality of analog-to-digital converters included in the ADC unit 130a. In some embodiments, the column scanning circuit 140a may include a column decoder that selects one of the plurality of analog-to-digital converters and a column driver that applies an output of the selected analog-to-digital converter to a horizontal transmission line. The horizontal transmission line may have a bit width corresponding to that of the digital output signal.

The control unit 200a may control the ADC unit 130a, the row scanning circuit 120a, the column scanning circuit 140a and the light source module 300a. The control unit 200a may provide the ADC unit 130a, the row scanning circuit 120a, the column scanning circuit 140a and the light source module 300a with control signals, such as a clock signal, a timing control signal, etc. In some embodiments, the control unit 200a may include a control logic circuit, a phase locked loop circuit, a timing control circuit, a communication interface circuit, etc.

The light source module 300a may emit light of a desired (or, alternatively, a predetermined) wavelength. For example, the light source module 300a may emit infrared light or near-infrared light. The light source module 300a may include a first light source 310a, a second light source 320a and a lens 330a. The first light source 310a may be controlled by the control unit 200a to emit a first emitted light TX1 of which the intensity periodically changes in response to a first control signal CTL1 from the control unit 200a. For example, the intensity of the first emitted light TX1 may be controlled such that the intensity of the first emitted light TX1 has a waveform of a pulse wave, a sine wave, a cosine wave, etc. The second light source 320a may be controlled by the control unit 200a to emit a second emitted light TX2 of which the intensity periodically changes in response to a second control signal CTL2 from the control unit 200a. For example, the intensity of the second emitted light TX2 may be controlled such that the intensity of the second emitted light TX2 has a waveform of a pulse wave, a sine wave, a cosine wave, etc. The first and second control signals CTL1 and CTL2 may controls the light source module 300a such that the first emitted light TX1 and the second emitted light TX2 may have different enabling pulse width with respect to each other. The first and second light source 310a and 320a may be implemented by a light emitting diode (LED), a laser diode, etc. The lens 330a may be configured to focus the first and second emitted lights TX1 and TX2 on the object 50a.

The lens module 400a may include a light-receiving lens 410a and a filter 420a. The light-receiving lens 410a concentrates the received light RX reflected from the object 50a to be provided to the pixel array 110a. The filter 420a, for example an infrared filter, filters components having frequencies other than a frequency corresponding to an infrared light, such as visible light VL. The sensor unit 105a may convert the filtered received light RX to electrical signals.

Hereinafter, an operation of the three-dimensional image sensor 10a according to example embodiments will be described below.

The control unit 200a may control the light source module 300a to emit the first emitted light TX1 and the second emitted light TX2 having pulse widths of different enabling intervals with respect to each other using the first and second control signals CTL1 and CTL2. The first and second emitted lights TX1 and TX2 emitted by the light source module 300a may be reflected from the object 50a back to the three-dimensional image sensor 10a as the received light RX. The received light RX may enter the depth pixels after only the infrared components pass through the lens module 400a. The depth pixels may be activated by the row scanning circuit 120a to output analog signals corresponding to the received light RX. The ADC unit 130a may convert the analog signals output from the depth pixels into digital data DATA. The digital data DATA may be provided to the control unit 200a by the column scanning circuit 140a.

A calculation unit 210a included in the control unit 200a may calculate a distance of the object 50a from the three-dimensional image sensor 10a based on the digital data DATA.

The digital data DATA and/or the depth information may be provided to the digital signal processing circuit or the external host. In some embodiments, the pixel array 110a may include color pixels, and the color image information as well as the depth information may be provided to the digital signal processing circuit or the external host.

As described above, in the three-dimensional image sensor 10a according to example embodiments, since the light source module 300a includes the first and second light source 310a and 320a which emit the first emitted light TX1 and the second emitted light TX2 having pulse widths of different enabling intervals with respect to each other in response to the first and second control signals CTL1 and CTL2 from the control unit 200a, an over-saturation effect of the object 50a due to the a plurality of light sources having different enabling pulse widths may be prevented.

FIG. 12 illustrates relative positions of the light sources and the light-receiving lens in FIG. 11.

Referring to FIG. 12, the first and second light sources 310a and 320a may be arranged that the first and second light sources 310a and 310b may be opposed to each other with respect to the light-receiving lens 410a. For example, the first and second light sources 310a and 320a may be opposed to each other with respect to a center line CL. For example, the first and second light sources 310a and 320a may be opposed to each other with respect to a center axis of the light-receiving lens 410a. Although the first and second light sources 310a and 310b are illustrated in FIG. 12, a plurality of first light sources and a plurality of second light sources may be opposed to each other with respect to the light-receiving lens 410a.

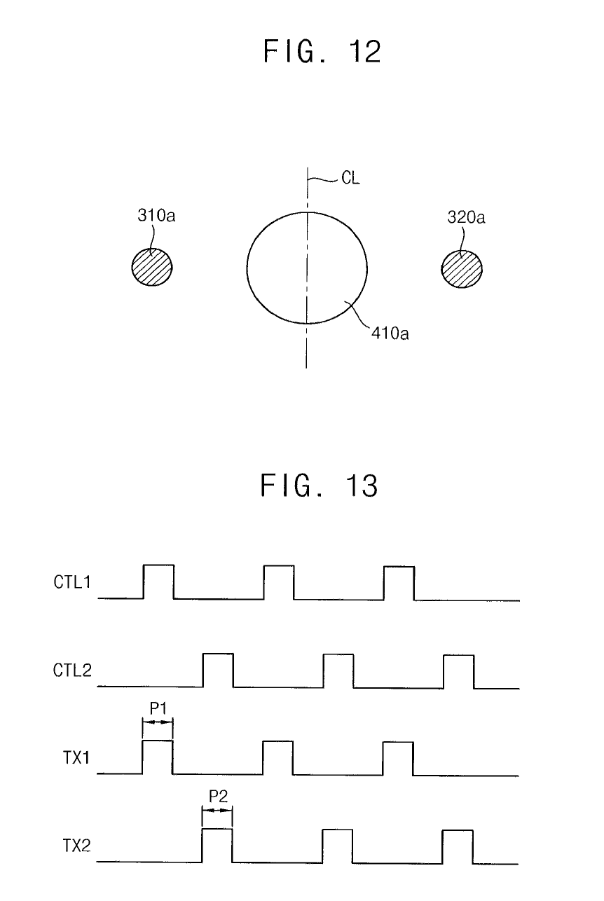

FIG. 13 illustrates the control signals and the emitted lights in FIG. 11.

Referring to FIG. 13, the first and second control signals CTL1 and CTL2 have a phase difference of 180 degrees and the first and second control signals CTL1 and CTL2 are alternately enabled. The first light source 310a may be periodically turned on/off in response to the first control signal CTL1, and the first light source 310a may output the first emitted light TX1 having a first pulse width P1. The second light source 320a may be periodically turned on/off in response to the second control signal CTL2, and the second light source 320a may output the second emitted light TX2 having a second pulse width P2. Since the first and second control signals CTL1 and CTL2 have a same period and the phase difference of 180 degrees, the first and second emitted lights TX1 and TX2 have a same period and a phase difference of 180 degrees. In addition, the first and second emitted lights TX1 and TX2 may have pulse widths of different enabling intervals. A width of the first pulse P1 may be same as a width of the second pulse P2.

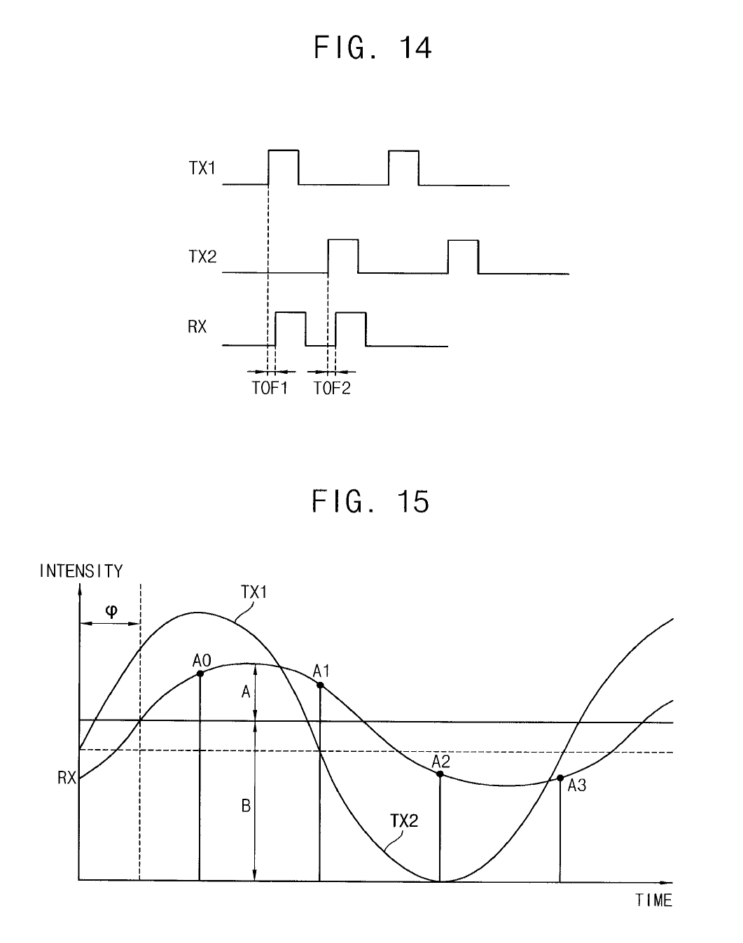

FIG. 14 illustrates the emitted lights and the received light in FIG. 11.

Referring to FIG. 14, a first TOF (TOF1) and a second TOF (TOF2) are illustrated. The first TOF (TOF1) may correspond to a phase difference between the first emitted light TX1 and the received light RX, and the second TOF (TOF2) may correspond to a phase difference between the second emitted light TX2 and the received light RX. Since the first and second emitted lights TX1 and TX2 have a same period and a phase difference of 180 degrees, the first TOF (TOF1) may be same as the second TOF (TOF2).

FIG. 15 is a diagram for describing an example of calculating a distance of an object by a three-dimensional image sensor of FIG. 11.

In FIG. 15, the first and second emitted light TX1 and TX2 is represented as the emitted light TX, and the intensity of the first emitted light TX1, the second emitted light TX2 and the received light RX may have a waveform of a sine wave.

The description of an example of calculating a distance of the object 50a by the three-dimensional image sensor 10a of FIG. 11 may be substantially similar to the example of calculating a distance of the object 50 by three-dimensional image sensor 10 of FIG. 1, and thus the detailed description will be omitted. The above described Equations 1 through 4 may be applicable to the example of calculating the distance of the object 50a by the three-dimensional image sensor 10a of FIG. 11 on condition that the polarized light PRX may be replaced with the received light RX.

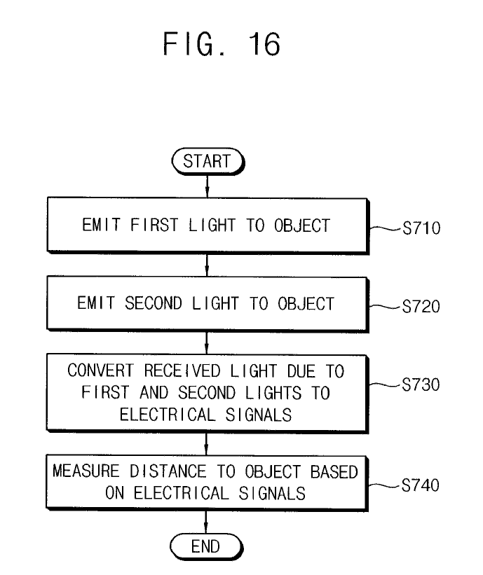

FIG. 16 is a flow chart illustrating an example of a method of measuring a distance of an object by a three-dimensional image sensor according to the still another example embodiment.

Referring to FIGS. 11, 12, 14, 15 and 16, a first light source 310a of a light source module 300a emits a first emitted light TX1 to an object 50a (S710). A second light source 320a of the light source module 300a emits a second emitted light TX2 to the object 50a (S720). A sensor unit 105a converts a received light RX that the first and second emitted lights TX1 and TX2 are reflected from the object 50a to electrical signals (S730). The control unit 200a measures a distance of the object 50a from the three-dimensional image sensor 10a based on the electrical signals. As described above, the first and second emitted lights TX1 and TX2 have a same period and a phase difference of 180 degrees.

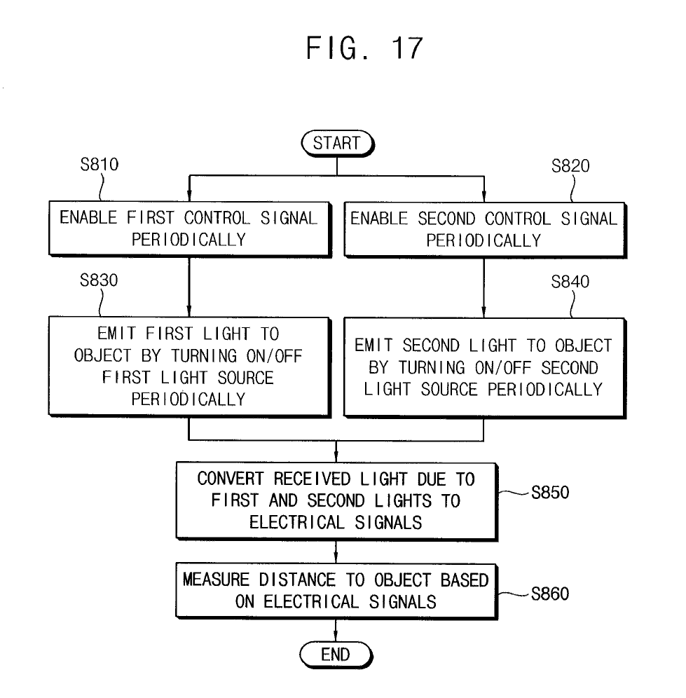

FIG. 17 is a flow chart illustrating another example of a method of measuring a distance of an object by a three-dimensional image sensor according to the still another example embodiment.

Referring to FIGS. 11, 12, 14, 15 and 17, a first control signal CTL1 is periodically enabled in a control unit 200a of a three-dimensional image sensor 10a (S810). A second control signal CTL2 is periodically enabled in the control unit 200a of the three-dimensional image sensor 10a (S820). A first emitted light TX1 is emitted to an object 50a by periodically turning on/off the first light source 310a in response to the first control signal CLT1 (S830). A second emitted light TX2 is emitted to the object 50a by periodically turning on/off the second light source 320a in response to the second control signal CLT2 (S840). Since the first and second control signals CTL1 and CTL2 are alternately enabled, and first and second emitted lights TX1 and TX2 may have pulse widths of different enabling intervals. As described above, the first and second emitted lights TX1 and TX2 have a same period and a phase difference of 180 degrees. A sensor unit 105a converts a received light RX that the first and second emitted lights TX1 and TX2 are reflected from the object 50a to electrical signals (S850). The control unit 200a measures a distance of the object 50a from the three-dimensional image sensor 10a based on the electrical signals.

FIG. 18 is a diagram illustrating an example of a sensor unit of a three-dimensional image sensor according to the still another example embodiment. FIG. 18 illustrates an example of the pixel array 110a includes depth pixels and color pixels.

Referring to FIG. 18, a sensor unit 750 includes a pixel array C/Z PX where a plurality of color pixels and a plurality of depth pixels are arranged, a color pixel select circuit (including color pixel row select circuit CROW and color pixel column select circuit CCOL), a depth pixel select circuit (including depth pixel row select circuit ZROW and depth pixel column select circuit ZCOL), a color pixel converter CADC, and a depth pixel converter ZADC. The color pixel select circuit (including color pixel row select circuit CROW and color pixel column select circuit CCOL) and the color pixel converter CADC may provide image information CDTA by controlling the color pixels included in the pixel array C/Z PX, and the depth pixel select circuit (including depth pixel row select circuit ZROW and depth pixel column select circuit ZCOL) and the depth pixel converter ZADC may provide depth information ZDTA by controlling the depth pixels included in the pixel array C/Z PX.

As described above, in the three-dimensional image sensor, components for controlling the color pixels and components for controlling the depth pixels may independently operate to provide the color data CDTA and the depth data ZDTA of an image.

Although it is described that the sensor unit 105a of the three-dimensional image sensor 10a of FIG. 11 may be implemented with the sensor unit 750 of FIG. 18, respective sensor units 105 and 155 in FIGS. 1 and 7 may employ the sensor unit 750 of FIG. 18.

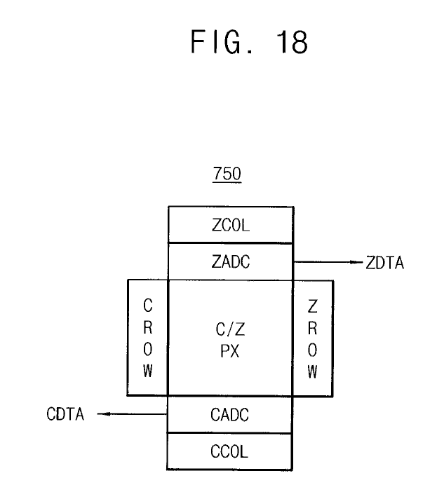

FIG. 19 is a block diagram illustrating an example of a camera including a three-dimensional image sensor according to a further example embodiment.

Referring to FIG. 19, a camera (also referred to as an image pick-up device) 800a includes a receiving lens 810a, a three-dimensional image sensor 900a and an engine unit 840a. The three-dimensional image sensor 900a may include a three-dimensional image sensor chip 820a and a light source module 830a. In some embodiments, the three-dimensional image sensor chip 820a and the light source module 830a may be implemented as separate devices, or may be implemented such that at least one component of the light source module 830a is included in the three-dimensional image sensor chip 820a. The three-dimensional image sensors 10 and 50 of FIGS. 1 and 7 may be respectively employed as the three-dimensional image sensor 900a. The light source module 830a may include a light source 831a and a lens 832a.

The receiving lens 810a may focus incident light on a photo-receiving region (e.g., depth pixels and/or color pixels) of the three-dimensional image sensor chip 820a. The three-dimensional image sensor chip 820a may generate data DATA1 including depth information and/or color image information based on the incident light passing through the receiving lens 810a. For example, the data DATA1 generated by the three-dimensional image sensor chip 820a may include depth data generated using infrared light or near-infrared light emitted by the light source module 830a, and red, green, blue (RGB) data of a Bayer pattern generated using external visible light VL. The three-dimensional image sensor chip 820a may provide the data DATA1 to the engine unit 840a in response to a clock signal CLK. In some embodiments, the three-dimensional image sensor chip 820a may interface with the engine unit 840a using a mobile industry processor interface (MIPI) and/or a camera serial interface (CSI).

The engine unit 840a may control the three-dimensional image sensor 900a. The engine unit 840a may process the data DATA1 received from the three-dimensional image sensor chip 820a. For example, the engine unit 840a may generate three-dimensional color data based on the received data DATAL In other examples, the engine unit 840a may generate luminance, chrominance (YUV) data including a luminance component (Y), a difference between the luminance component and a blue component (U), and a difference between the luminance component and a red component (V) based on the RGB data, or may generate compressed data, such as Joint Photographic Experts Group (JPEG) data. The engine unit 840a may be coupled to a host/application 850a, and may provide data DATA2 to the host/application 850a based on a master clock signal MCLK. In some embodiments, the engine unit 840a may interface with the host/application 850a using a serial peripheral interface (SPI) and/or an inter integrated circuit (I2C) interface.

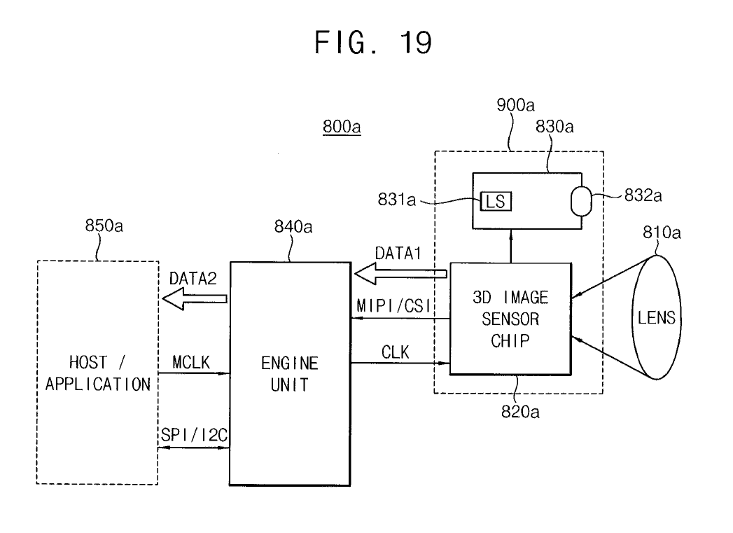

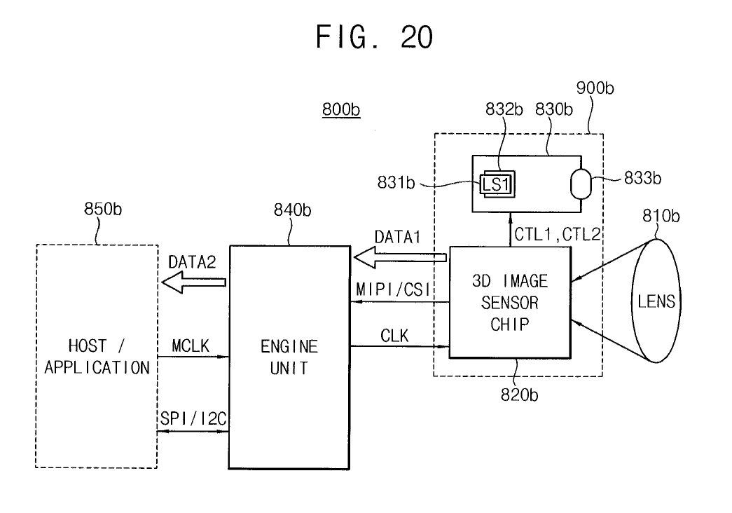

FIG. 20 is a block diagram illustrating another example of a camera including a three-dimensional image sensor according to yet a further example embodiment.

Referring to FIG. 20, a camera (also referred to as an image pick-up device) 800b includes a receiving lens 810b, a three-dimensional image sensor 900b and an engine unit 840b. The three-dimensional image sensor 900b may include a three-dimensional image sensor chip 820b and a light source module 830b. In some embodiments, the three-dimensional image sensor chip 820b and the light source module 830b may be implemented as separate devices, or may be implemented such that at least one component of the light source module 830b is included in the three-dimensional image sensor chip 820b. The three-dimensional image sensor 10a of FIG. 11 may be employed as the three-dimensional image sensor 900b. The light source module 830b may include a first light source 831b, a second light source 832b and a lens 833b. The first and second light sources 831b and 832b may be implemented with a light emitting diode (LED) or a laser diode (LD). The three-dimensional image sensor chip 820b may alternately turning on/off the first and second light sources 831b and 832b to emit lights having pulse widths of different enabling intervals with respect to each other by alternately enabling first and second control signals CLT1 and CLT2.

Each operation of the receiving lens 810b, the engine unit 840b and a host/application 850b may be substantially same as each operation of the receiving lens 810a, the engine unit 840a and the host/application 850a in FIG. 19, and thus, detailed description on operations of the receiving lens 810b, the engine unit 840b and the host/application 850b will be omitted.

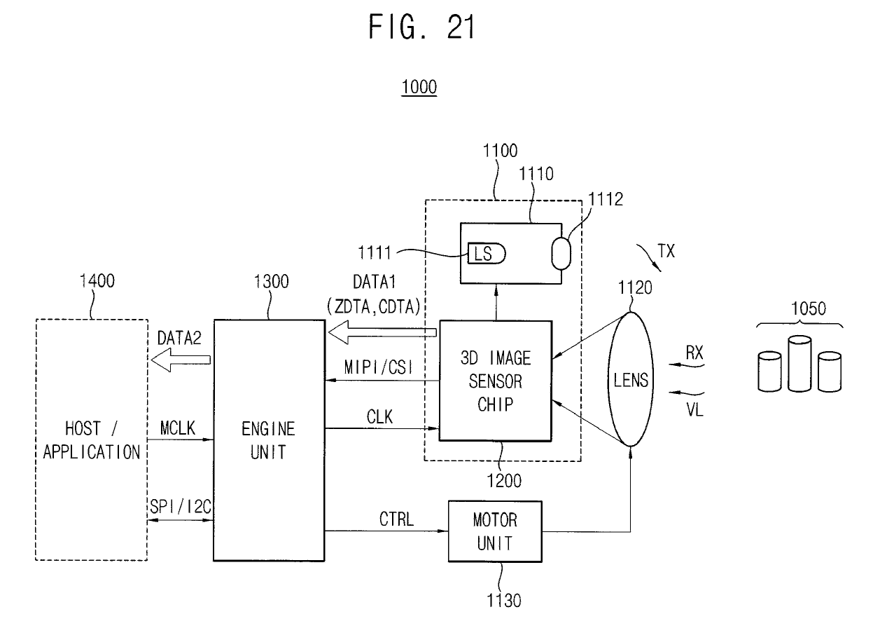

FIG. 21 is a block diagram illustrating a camera including a three-dimensional image sensor according to an even further example embodiment.

Referring to FIG. 21, a camera (also referred to as an image pick-up device) 1000 includes a receiving lens 1120, a three-dimensional image sensor (or also referred to as a sensor module) 1100, a motor unit 1130 and an engine unit 1300. The three-dimensional image sensor 1100 may include a three-dimensional image sensor chip 1200 and a light source module 1110. In some embodiments, the three-dimensional image sensor chip 1200 and the light source module 1110 may be implemented as separate devices, or may be implemented such that at least one component of the light source module 1110 is included in the three-dimensional image sensor chip 1200.

The receiving lens 1120 may focus incident light on a photo-receiving region (e.g., depth pixels and/or color pixels) of the three-dimensional image sensor chip 1200. The three-dimensional image sensor chip 1200 may generate depth data ZDTA including depth information of a plurality of objects 1050 based on emitted light TX reflected from the plurality of objects 1050 as received light RX, and may provide the depth data ZDTA to the engine unit 1300. The engine unit 1300 may generate a depth map including depth information of the plurality of objects 1050 based on the depth data ZDTA, may segment the plurality of objects 1050 in the depth map based on the depth map, and may generate a control signal CTRL for controlling the receiving lens 1120 based on the segmented objects. That is, the engine unit 1300 may select one of the plurality of objects 1050 in the depth map, may set the selected object as a focusing region, and may generate the control signal CTRL for focusing the receiving lens 1120 on the focusing region.

The motor unit 1130 may control the focusing of the receiving lens 1120 on the selected object by moving the receiving lens 1120 in response to the control signal CTRL. The three-dimensional image sensor chip 1200 may generate color data CDTA of the objects 1050 based on visible light VL which are reflected from the objects 1050 and received through the focus-adjusted receiving lens 1120, and may provide the color data CDTA to the engine unit 1300.

The light source module 1110 may include a light source 1111 and a lens 1112. The light source 1111 may generate infrared light or near-infrared light, and the lens 1112 may focus the infrared light or near-infrared light on the objects 1050.

The three-dimensional image sensor chip 1200 may provide data DATA1, including the depth data ZDTA and/or the color data CDTA, to the engine unit 1300 in response to a clock signal CLK. In some embodiments, the three-dimensional image sensor chip 1200 may interface with the engine unit 1300 using a mobile industry processor interface (MIPI) and/or a camera serial interface (CSI).

The engine unit 1300 may control the three-dimensional image sensor 1100 and the motor unit 1130. The engine unit 1300 may process the data DATA1 received from the three-dimensional image sensor chip 1200. For example, the engine unit 1300 may generate three-dimensional color data based on the received data DATA1. In other examples, the engine unit 1300 may generate YUV data including a luminance component, a difference between the luminance component and a blue component, and a difference between the luminance component and a red component based on the RGB data, or may generate compressed data, such as Joint Photographic Experts Group (JPEG) data. The engine unit 1300 may be coupled to a host/application 1400, and may provide data DATA2 to the host/application 1400 based on a master clock signal MCLK. In some embodiments, the engine unit 1300 may interface with the host/application 1400 using a serial peripheral interface (SPI) and/or an inter integrated circuit (I2C) interface.

In an example embodiment of FIG. 21, the receiving lens 1120 may have relatively short depth of field. That is, the receiving lens 1120 may be focused on one of the objects 1050.

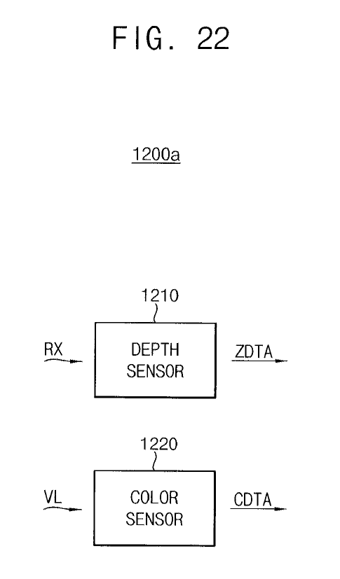

FIG. 22 is a block diagram illustrating an example of the three-dimensional image sensor chip in FIG. 21 according to the even further example embodiment.

Referring to FIG. 22, a three-dimensional image sensor chip 1200a may include a depth sensor 1210 and a color sensor 1220. The depth sensor 1210 may include a depth pixel array having a plurality of depth pixels, and may generate the depth data ZDTA of the objects 1050 based on the received light RX reflected from the objects 1050. The color sensor 1220 may include a color pixel array having a plurality of color pixels, and may generate the color data CDTA of the objects 1050 based on the visible light VL from the objects 1050.

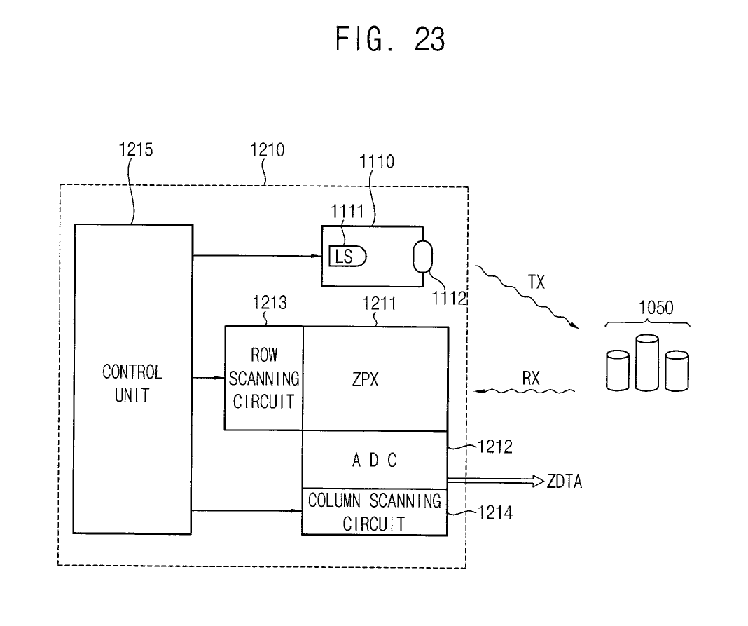

FIG. 23 is a block diagram illustrating an example of depth sensor in FIG. 22 according to the even further example embodiment.

In FIG. 23, the light source module 1110 is illustrated together with the depth sensor 1210.

Referring to FIG. 23, the depth sensor 1210 may include a depth pixel array 1211, an analog-to-digital conversion (ADC) unit 1212, a row scanning circuit 1213, a column scanning circuit 1214, a control unit 1215 and the light source module 1110.

The depth pixel array 1211 may include depth pixels receiving light RX that is emitted by the light source module 1110 and is reflected from the object 1050. The depth pixels may convert the received light RX into electrical signals. The depth pixels may provide information about a distance of the objects 1050 from the depth sensor 1210 and/or black-and-white image information.

The ADC unit 1212 may convert an analog signal output from the depth pixel array 1211 into a digital signal. In some embodiments, the ADC unit 1212 may perform a column ADC that converts analog signals in parallel using a plurality of analog-to-digital converters respectively coupled to a plurality of column lines. In other embodiments, the ADC unit 1212 may perform a single ADC that sequentially converts the analog signals using a single analog-to-digital converter.

In some embodiments, the ADC unit 1212 may further include a correlated double sampling (CDS) unit for extracting an effective signal component. In some embodiments, the CDS unit may perform an analog double sampling that extracts the effective signal component based on a difference between an analog reset signal including a reset component and an analog data signal including a signal component. In other embodiments, the CDS unit may perform a digital double sampling that converts the analog reset signal and the analog data signal into two digital signals and extracts the effective signal component based on a difference between the two digital signals. In still other embodiments, the CDS unit may perform a dual correlated double sampling that performs both the analog double sampling and the digital double sampling.

The row scanning circuit 1213 may receive control signals from the control unit 1215, and may control a row address and a row scan of the depth pixel array 1211. To select a row line among a plurality of row lines, the row scanning circuit 1213 may apply a signal for activating the selected row line to the depth pixel array 1211. In some embodiments, the row scanning circuit 1213 may include a row decoder that selects a row line of the depth pixel array 1211 and a row driver that applies a signal for activating the selected row line.

The column scanning circuit 1214 may receive control signals from the control unit 1215, and may control a column address and a column scan of the depth pixel array 1211. The column scanning circuit 1214 may output a digital output signal from the ADC unit 1212 to a digital signal processing circuit (not shown) or to an external host (not shown). For example, the column scanning circuit 1214 may provide the ADC unit 1212 with a horizontal scan control signal to sequentially select a plurality of analog-to-digital converters included in the ADC unit 1212. In some embodiments, the column scanning circuit 1214 may include a column decoder that selects one of the plurality of analog-to-digital converters and a column driver that applies an output of the selected analog-to-digital converter to a horizontal transmission line. The horizontal transmission line may have a bit width corresponding to that of the digital output signal.

The control unit 1215 may control the ADC unit 1212, the row scanning circuit 1213, the column scanning circuit 1214 and the light source module 1110. The control unit 1215 may provide the ADC unit 1212, the row scanning circuit 1213, the column scanning circuit 1214 and the light source module 1110 with control signals, such as a clock signal, a timing control signal, etc. In some embodiments, the control unit 1215 may include a control logic circuit, a phase locked loop circuit, a timing control circuit, a communication interface circuit, etc.

The light source module 1110 may emit light of a desired (or, alternatively, a predetermined) wavelength. For example, the light source module 1110 may emit infrared light or near-infrared light. The light source 1110 may be controlled by the control unit 1215 to emit the emitted light TX of which the intensity periodically changes. For example, the intensity of the emitted light TX may be controlled such that the intensity of the emitted light TX has a waveform of a pulse wave, a sine wave, a cosine wave, etc. The light source 1111 may be implemented by a light emitting diode (LED), a laser diode, etc.

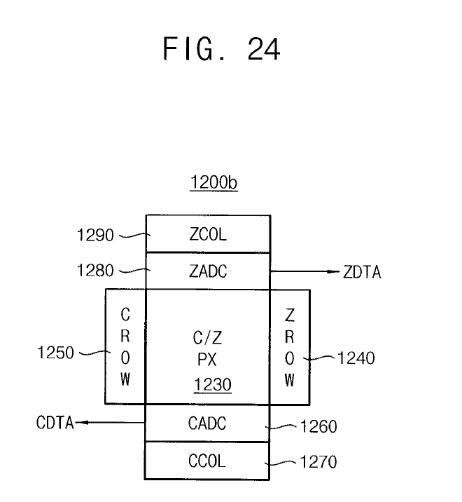

FIG. 24 is a block diagram illustrating another example of the three-dimensional image sensor chip in FIG. 21 according to the even further example embodiment.

Referring to FIG. 24, a three-dimensional image sensor chip 1200b may include a pixel array 1230 where a plurality of color pixels and a plurality of depth pixels are arranged, color pixel select circuits (including color pixel row select circuit 1250 and color pixel column select circuit 1270), depth pixel select circuits (including depth pixel row select circuit 1240 and depth pixel column select circuit 1290), a color pixel converter 1260, and a depth pixel converter 1280. The color pixel select circuits 1250 and 1270 and the color pixel converter 1260 may provide the color data CDTA by controlling the color pixels included in the pixel array 1230, and the depth pixel select circuits 1240 and 1290 and the depth pixel converter 1280 may provide the depth data ZDTA by controlling the depth pixels included in the pixel array 1230.

Although not illustrated in FIG. 24, a control circuit such as the control unit 1215 in FIG. 23 may be employed in the three-dimensional image sensor chip 1200b and may control the color pixel select circuits (including color pixel row select circuit 1250 and color pixel column select circuit 1270), the color pixel converter 1260, the depth pixel select circuits (including depth pixel row select circuit 1240 and depth pixel column select circuit 1290), and the depth pixel converter 1280.

In an example of FIG. 24, components for controlling the color pixels and components for controlling the depth pixels may independently operate to provide the color data CDTA and the depth data ZDTA of an image.

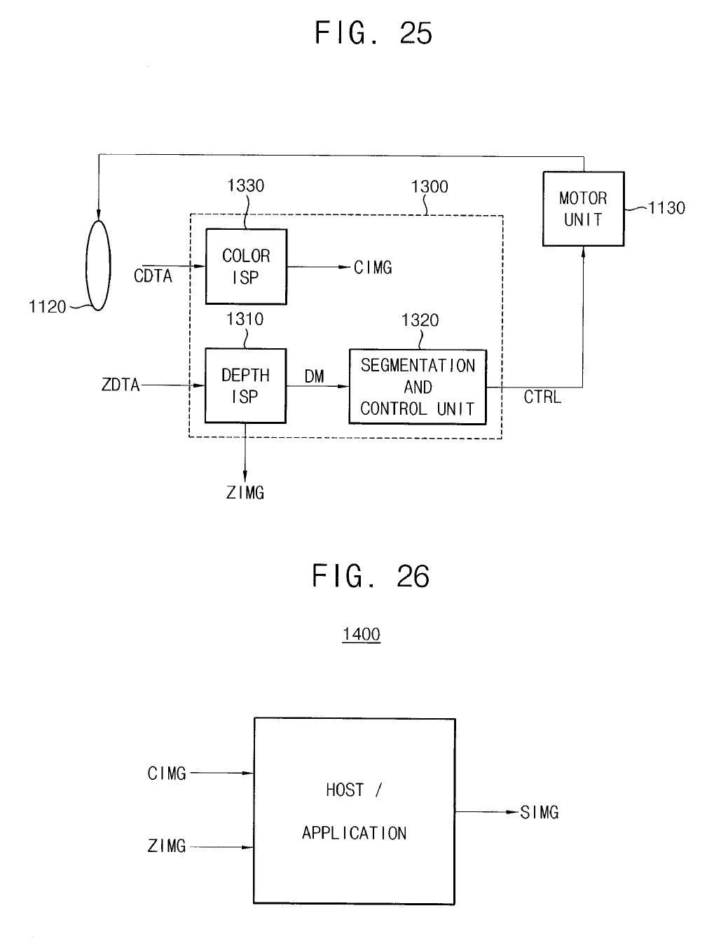

FIG. 25 is a block diagram illustrating an engine unit in FIG. 21 according to the even further example embodiment.

In FIG. 25, the receiving lens 1120 and the motor unit 1130 are illustrated together with the engine unit 1300.

Referring to FIG. 25, the engine unit 1300 may include a first image signal processor (ISP) 1310, a segmentation and control unit 1320 and a second ISP 1330.

The first ISP (depth ISP) 1310 may process the depth data ZDTA to generate a depth image ZIMG and a depth map DM of the objects 1050. The depth map DM may include depth information of the objects 1050, and the depth image ZIMG may be a black-and-white image including depth information of the objects 1050. The depth image ZIMG may be provided to the host/application 1400, and the depth map DM may be provided to the segmentation and control unit 1320. The segmentation and control unit 1320 may segment the objects 1050 in the depth map DM based on the depth map DM and may generate the control signal CTRL for controlling the receiving lens 1120 based on the segmented object. The control signal CTRL may be provided to the motor unit 1130 and the motor unit 1130 may control the focusing of the receiving lens 1120 on the object selected in the segmentation and control unit 1320 by moving the receiving lens 1120 in response to the control signal CTRL. The three-dimensional image sensor chip 1200 may generate the color data CDTA of the objects 1050 based on visible light VL which is reflected from the objects 1050 and may provide the color data CDTA to the second ISP (color ISP) 1330. The second ISP 1330 may process the color data CDTA to generate a color image CIMG. The second ISP 1330 may perform color image processing on each of the objects 1050 according to respective distances of the objects 1050 from the three-dimensional image sensor chip 1200.

As described above, in the camera 1000 according to example embodiments, the depth map DM is generated based on depth information of the objects 1050, one of the objects 1050 to be focused on by the receiving lens 1120 is selected based on the depth map DM, the receiving lens 1120 is moved such that the receiving lens 1120 is focused on the selected object, and each of the objects 1050 may be processed to a color image according to respective distances between the receiving lens 1120 (or the three-dimensional image sensor chip 1200) and respective objects 1050. That is, the object selected in the segmentation and control unit 1320 may be processed with more calculations while objects other than the selected object may be processed with less calculations.

FIG. 26 is a block diagram illustrating the host/application in FIG. 21 according to the even further example embodiment.

Referring to FIG. 26, the host/application 1400 may compose the color image CIMG and the depth image ZIMG to generate a stereo image SIMG, i.e., a three-dimensional color image. That is, the host/application 1400 may compose the depth image ZIMG which is a black-and-white image and includes depth information of the objects 1050 and the two-dimensional color image CIMG which is processed with being focused on one of the objects 1050 to generate a three-dimensional color image (stereo image) which is more realistic.

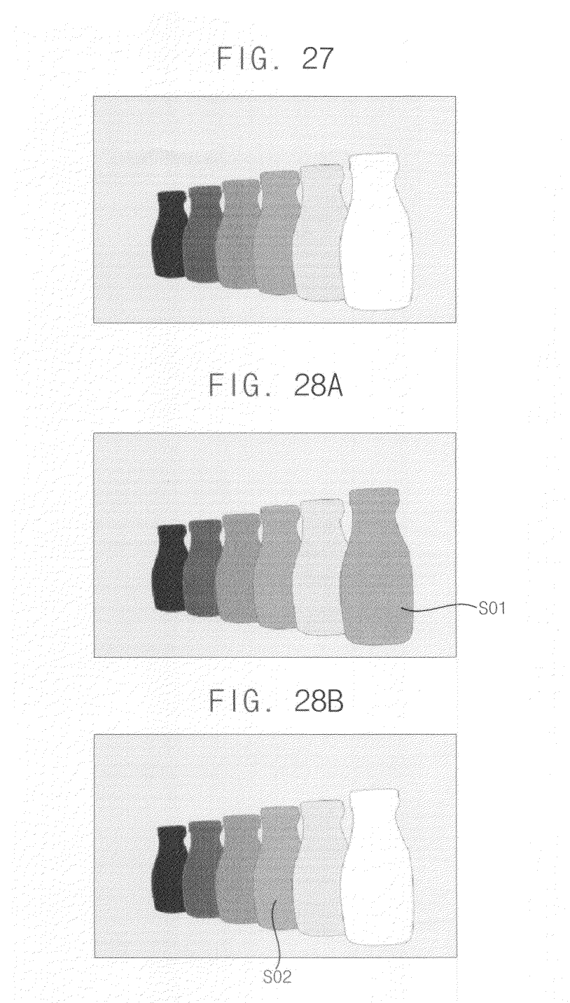

FIG. 27 illustrates a depth map of a plurality of objects according to an example embodiment.

FIGS. 28A through 28C respectively illustrate a selected object in the depth map of FIG. 27 according to the example embodiment.

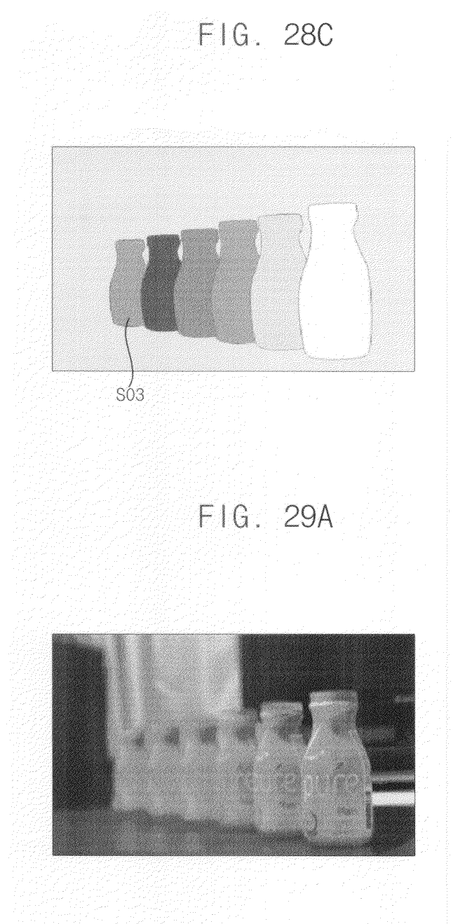

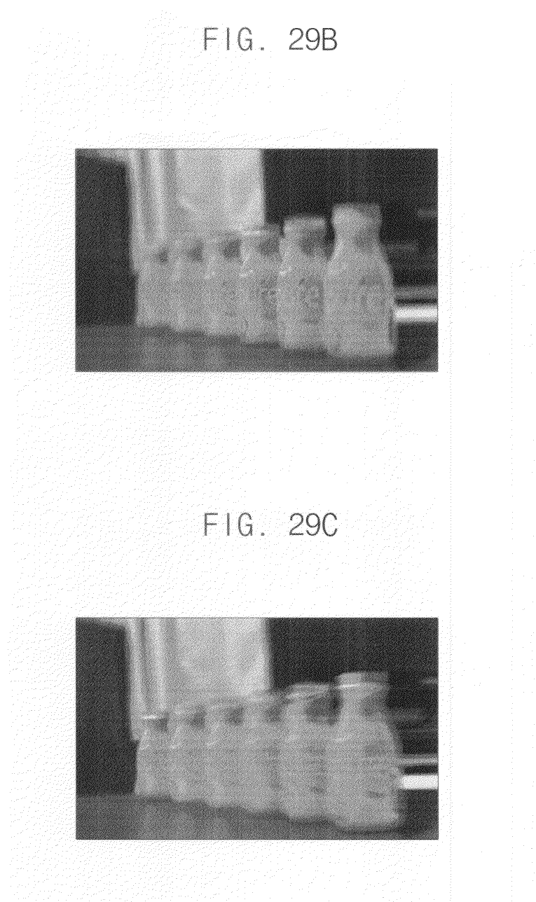

FIGS. 29A through 29C respectively illustrate a color image focused on the respective selected object in FIGS. 28A through 28C according to the example embodiment.

Hereinafter, there will be detailed description on operation of the camera 1000 with reference FIGS. 21 to 29C.

When the objects 1050 are positioned at different distances from the camera 1000, the depth map DM of FIG. 27 may be obtained according to differences of arrival times of the received light RX from the respective objects 1050 to the three-dimensional image sensor chip 1200. When a user selects an object S01 as in FIG. 28A, the segmentation and control unit 1320 may provide the motor unit 1130 with the control signal CTRL for controlling the receiving lens 1120 such that the receiving lens 1120 may be focused on the selected object S01. The motor unit 1130 moves the receiving lens 1120 (for example to a direction of the three-dimensional image sensor chip 1200) such that receiving lens 1120 is focused on the selected object S01. The three-dimensional image sensor chip 1200 generates the color data CDTA of the objects 1050 based on visible light VL through the receiving lens 1120 which is focused on the selected object S01 and provides the color data CDTA to the second ISP 1330. The second ISP 1330 processes the color data CDTA to provide a color image CIMG as in FIG. 29A.

For example, when the user selects an object S02 as in FIG. 28B, the segmentation and control unit 1320 may provide the motor unit 1130 with the control signal CTRL for controlling the receiving lens 1120 such that the receiving lens 1120 may be focused on the selected object S02. The motor unit 1130 moves the receiving lens 1120 (for example to a direction of the three-dimensional image sensor chip 1200 or the objects 1050) such that receiving lens 1120 is focused on the selected object S02. The three-dimensional image sensor chip 1200 generates the color data CDTA of the objects 1050 based on visible light VL through the receiving lens 1120 which is focused on the selected object S02 and provides the color data CDTA to the second ISP 1330. The second ISP 1330 processes the color data CDTA to provide a color image CIMG as in FIG. 29B.

For example, when the user selects an object S03 as in FIG. 28C, the segmentation and control unit 1320 may provide the motor unit 1130 with the control signal CTRL for controlling the receiving lens 1120 such that the receiving lens 1120 may be focused on the selected object S03. The motor unit 1130 moves the receiving lens 1120 (for example to a direction of the objects 1050) such that receiving lens 1120 is focused on the selected object S03. The three-dimensional image sensor chip 1200 generates the color data CDTA of the objects 1050 based on visible light VL through the receiving lens 1120 which is focused on the selected object S03 and provides the color data CDTA to the second ISP1330. The second ISP 1330 processes the color data CDTA to provide a color image CIMG as in FIG. 29C.

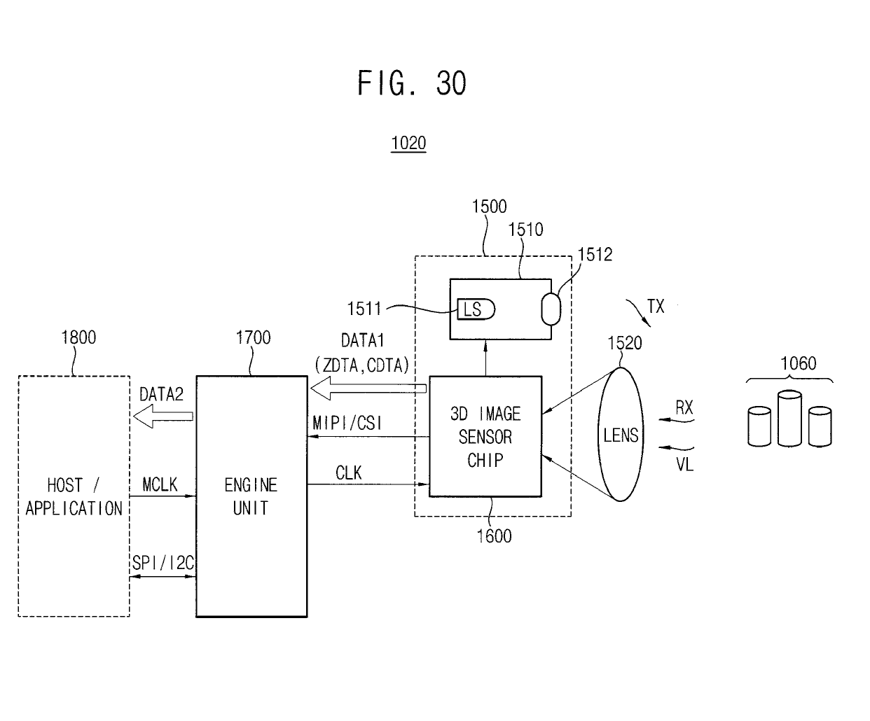

FIG. 30 is a block diagram illustrating a camera including a three-dimensional image sensor according to a still further example embodiment.

Referring to FIG. 30, a camera (also referred to as an image pick-up device) 1020 includes a receiving lens 1520, a three-dimensional image sensor (or also referred to as a sensor module) 1500, and an engine unit 1700. The camera 1020 may further include a host/application 1800. The three-dimensional image sensor 1500 may include a three-dimensional image sensor chip 1600 and a light source module 1510. In some embodiments, the three-dimensional image sensor chip 1600 and the light source module 1510 may be implemented as separate devices, or may be implemented such that at least one component of the light source module 1510 is included in the three-dimensional image sensor chip 1600.

The receiving lens 1520 may focus incident light on a photo-receiving region (e.g., depth pixels and/or color pixels) of the three-dimensional image sensor chip 1600. The three-dimensional image sensor chip 1600 may generate depth data ZDTA including depth information of a plurality of objects 1050 based on received light RX reflected from the plurality of objects 1060, may generate color data CDTA including color information of the objects 1060 based on visible light VL from the objects 1060 and may provide the depth data ZDTA and the color data CDTA to the engine unit 1700. The engine unit 1700 may generate a depth map including depth information of the plurality of objects 1060 based on the depth data ZDTA, may perform image blurring process on the color data CDTA based in the depth map.

The light source module 1510 may include a light source 1511 and a lens 1512. The light source 1511 may generate infrared light or near-infrared light, and the lens 1512 may focus the infrared light or near-infrared light on the objects 1060.

The three-dimensional image sensor (or sensor module) 1500 may provide data DATA1 including the depth data ZDTA and/or the color data CDTA to the engine unit 1700 in response to a clock signal CLK. In some embodiments, the three-dimensional image sensor chip 1600 may interface with the engine unit 1700 using a mobile industry processor interface (MIPI) and/or a camera serial interface (CSI).

The engine unit 1700 may control the three-dimensional image sensor 1500. The engine unit 1700 may process the data DATA1 received from the three-dimensional image sensor chip 1600. For example, the engine unit 1700 may generate three-dimensional color data based on the received data DATA1. In other examples, the engine unit 1700 may generate YUV data including a luminance component, a difference between the luminance component and a blue component, and a difference between the luminance component and a red component based on the RGB data, or may generate compressed data, such as Joint Photographic Experts Group (JPEG) data. The engine unit 1700 may be coupled to a host/application 1800, and may provide data DATA2 to the host/application 1800 based on a master clock signal MCLK. In some embodiments, the engine unit 1700 may interface with the host/application 1700 using a serial peripheral interface (SPI) and/or an inter integrated circuit (I2C) interface.

In an example embodiment of FIG. 30, the receiving lens 1520 may have relatively long depth of field. That is, the receiving lens 1520 may be focused on all of the objects 1060.

The three-dimensional image sensor chip 1600 may have configuration of the three-dimensional image sensor chip 1200a of FIG. 22 or the three-dimensional image sensor chip 1200b of FIG. 24. Therefore, detailed description of operation and configuration of the three-dimensional image sensor chip 1600 will be omitted. That is, the three-dimensional image sensor chip 1600 may include a depth sensor having depth pixels and a color sensor having color pixels which are separated or include a depth/color sensor having pixel array which includes depth pixels and color pixels and provides the depth data ZDTA and the color data CDTA simultaneously.

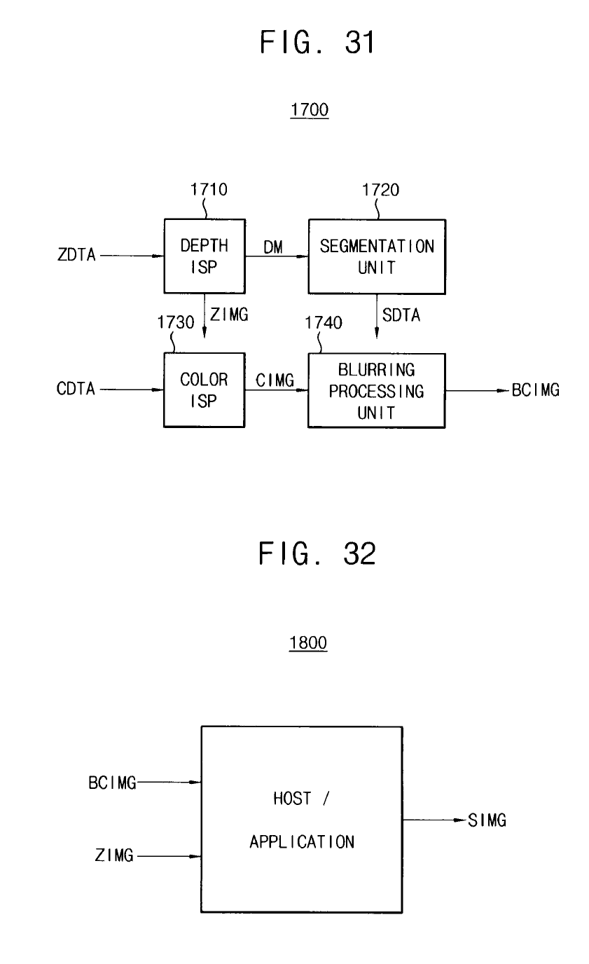

FIG. 31 is a block diagram illustrating an engine unit in FIG. 30 according to the still further example embodiment.

Referring to FIG. 31, the engine unit 1700 may include a first image signal processor (ISP) 1710, a segmentation unit 1720, a second ISP 1730 and a blurring processing unit 1740. The first ISP 1710 may process the depth data ZDTA to generate a depth image ZIMG and a depth map DM of the objects 1060. The depth image ZIMG may be provided to the host/application 1800, and the depth map DM may be provided to the segmentation unit 1720. The segmentation unit 1720 may segment the objects 1060 (select one of the objects 1060) in the depth map DM based on the depth map DM and may provide segmentation data SDTA of the segmented objects. The second ISP 1730 may process the color data CDTA to generate a color image CIMG of the objects 1060. The color image CIMG may be provided to the blurring processing unit 1740. The blurring processing unit 1740 may perform blurring process on objects other than the object selected in the segmentation unit 1720 based on the segmentation data SDTA to generate a blurred color image BCIMG. For example, the blurring processing unit 1740 may perform blurring process on objects other than the object selected in the segmentation unit 1720 by processing the objects other than the object selected with different blurring levels from the selected object based on respective relative distances between the objects other than the object selected and the selected object.

FIG. 32 is a block diagram illustrating the host/application in FIG. 30 according to the still further example embodiment.

Referring to FIG. 32, the host/application 1800 may compose the blurred color image BCIMG and the depth image ZIMG to generate a stereo image SIMG, i.e., a three-dimensional color image. That is, the host/application 1800 may compose the depth image ZIMG, which is a black-and-white image and includes depth information of the objects 1060, and the two-dimensional blurred color image BCIMG, which is generated by performing on objects other than the object selected in the segmentation unit 1720 based on the segmentation data SDTA, to generate a three-dimensional color image (stereo image) which is more realistic.

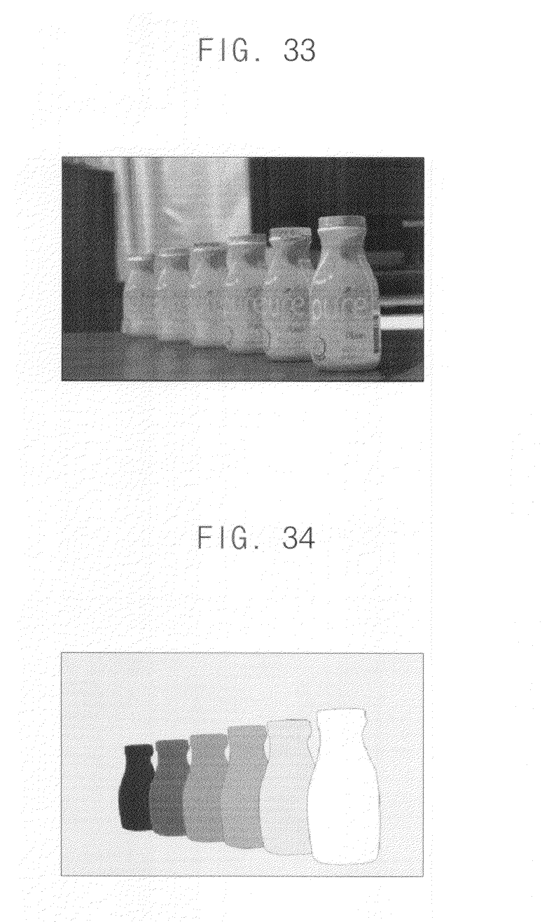

FIG. 33 illustrates a color image of a plurality of objects according to an example embodiment.

FIG. 34 illustrates depth map of a plurality of objects according to the example embodiment.

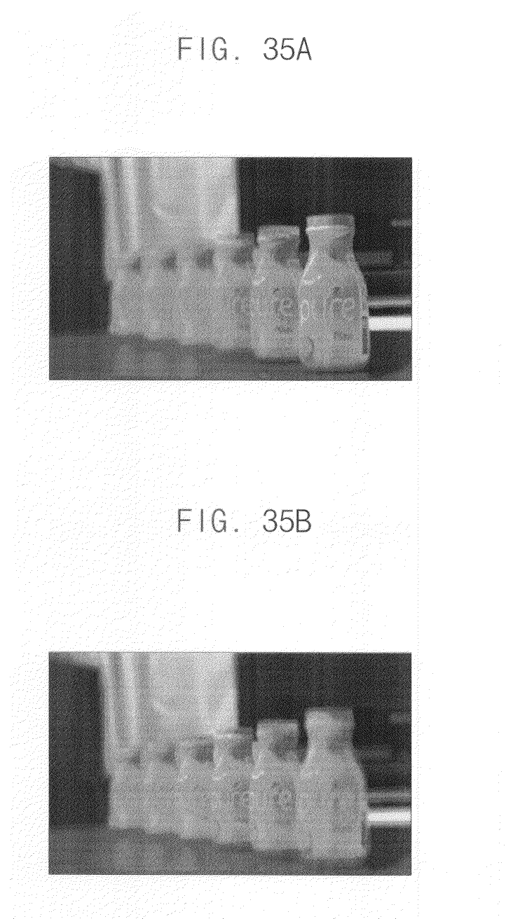

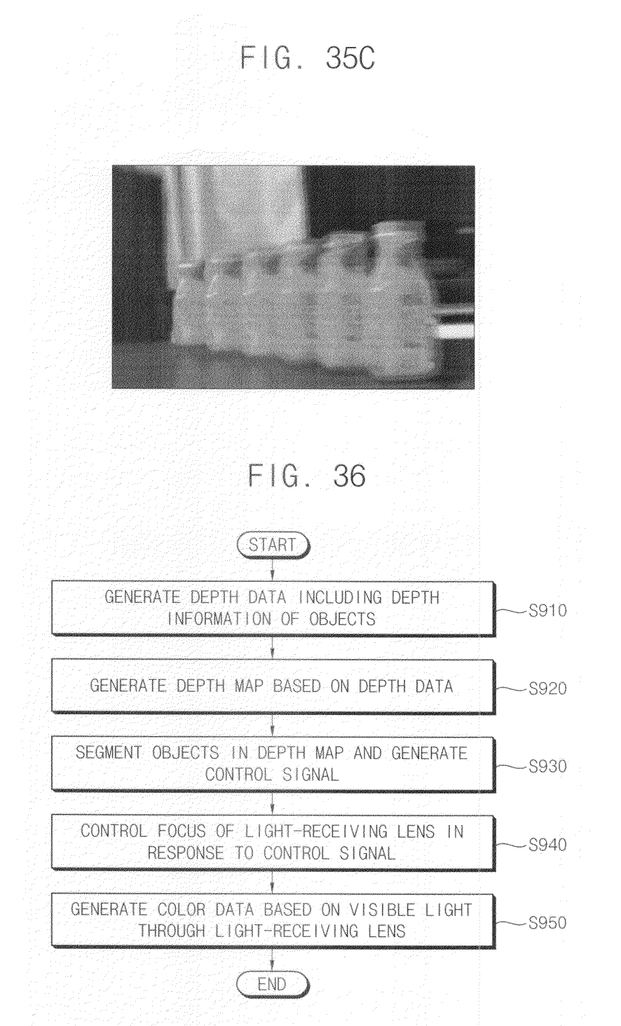

FIGS. 35A through 35C respectively illustrate a blurred color image of the respective selected object according to the example embodiment.

For convenience of explanation, FIGS. 35A and 35C respectively illustrate a blurred color image of the respective selected object in the depth map of FIG. 34 as in FIGS. 28A and 28C.

Hereinafter, there will be detailed description on operation of the camera 1020 with reference FIGS. 30 to 35C.

When the objects 1060 are positioned at different distances from the camera 1020, the depth map DM of FIG. 34 may be obtained according to differences of arrival times of the received light RX from the respective objects 1060 to the three-dimensional image sensor chip 1600. Since the receiving lens 1520 has relatively long depth of field, the color image CIMG of objects 1060 is as in FIG. 33 although the objects 1060 are positioned at different distances from the camera 1020. That is, the receiving lens 1120 is focused on all of the objects 1060.

For example, when a user selects an object S01 as in FIG. 28A, the segmentation unit 1720 may provide the blurring processing unit 1740 with the segmentation data SDTA indicating the selected object S01, and the blurring processing unit 1740 may perform blurring process on objects other than the selected object S01 based on respective relative distances between the objects other than the selected object and the selected object S01 to generate a blurred color image BCIMG in FIG. 35A.

For example, when a user selects an object S02 as in FIG. 28B, the segmentation unit 1720 may provide the blurring processing unit 1740 with the segmentation data SDTA indicating the selected object S02, and the blurring processing unit 1740 may perform blurring process on objects other than the selected object S02 based on respective relative distances between the objects other than the selected object and the selected object S02 to generate a blurred color image BCIMG in FIG. 35B.

For example, when a user selects an object S03 as in FIG. 28C, the segmentation unit 1720 may provide the blurring processing unit 1740 with the segmentation data SDTA indicating the selected object S03, and the blurring processing unit 1740 may perform blurring process on objects other than the selected object S03 based on respective relative distances between the objects other than the selected object and the selected object S03 to generate a blurred color image BCIMG in FIG. 35C.

FIG. 36 is a flow chart illustrating an example of a method of processing image according to an example embodiment.

Referring to FIGS. 21 to 29C and FIG. 36, a three-dimensional image sensor chip 1200 of a camera 1000 generates depth data ZDTA including depth information of a plurality of objects 1050 (S910). An engine unit 1300 may generate a depth map DM based on the depth data ZDTA (S920). The objects 1050 may be segmented in the depth map and a control signal CTRL for controlling a receiving lens 1120 may be generated (S930). A motor unit 1130 may control the receiving lens 1120 such that the receiving lens 1120 may be focused on the segmented object (S940). The three-dimensional image sensor chip 1100 may generate color data CDTA of the objects 1050 based on visible light VL which are reflected from the objects 1050 and passes through the receiving lens 1120 which is focused on the segmented object (S950). The receiving lens 1120 may have relatively short depth of field. That is, the receiving lens 1120 may be focused on one of the objects 1050.

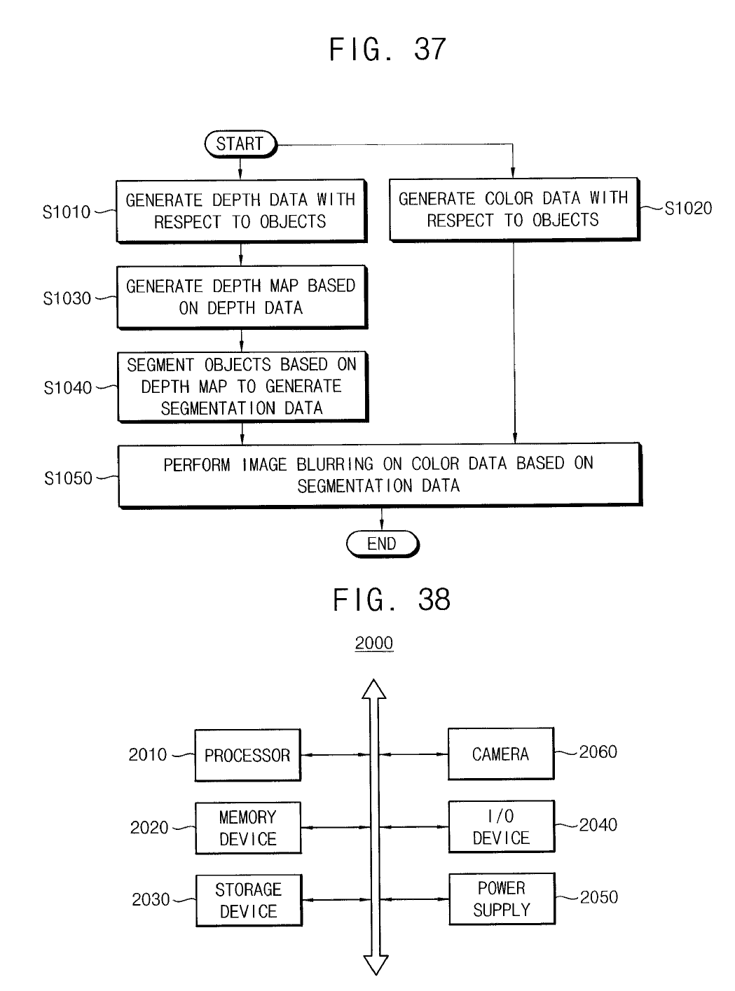

FIG. 37 is a flow chart illustrating another example of a method of processing image according to another example embodiment.

Referring to FIGS. 30 to 35C and FIG. 37, a three-dimensional image sensor chip 1600 of a camera 1020 generates depth data ZDTA including depth information of a plurality of objects 1060 (S1010). The three-dimensional image sensor chip 1600 generates color data CDTA including color information of the objects 1060 (S1020). An engine unit 1700 may generate a depth map DM based on the depth data ZDTA (S1030). The engine unit 1700 may segment the objects based on the depth map DM to provide segmentation data SDTA indicating the segmented object (S1040). The engine unit 1700 may perform a blurring process on objects other than the selected object to generate a blurred color image BCIMG (S1050). The receiving lens 1520 may have relatively long depth of field. That is, the receiving lens 1120 may be focused on all of the objects 1060.

FIG. 38 is a block diagram illustrating a computing system including a camera according to a further example embodiment.

Referring to FIG. 38, a computing system 2000 includes a processor 2010, a memory device 2020, a storage device 2030, an input/output (I/O) device 2040, a power supply 2050 and a camera 2060. Although it is not illustrated in FIG. 38, the computing system 2000 may further include a port for communicating with electronic devices, such as a video card, a sound card, a memory card, a USB device, etc.

The processor 2010 may perform specific calculations or tasks. For example, the processor 2010 may be a microprocessor, a central process unit (CPU), a digital signal processor, or the like. The processor 2010 may communicate with the memory device 2020, the storage device 2030 and the input/output device 2040 via an address bus, a control bus and/or a data bus. The processor 2010 may be coupled to an extension bus, such as a peripheral component interconnect (PCI) bus. The memory device 2020 may store data for operating the computing system 2000. For example, the memory device 2020 may be implemented by a dynamic random access memory (DRAM), a mobile DRAM, a static random access memory (SRAM), a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), etc. The storage device 2030 may include a solid state drive, a hard disk drive, a compact disc read-only memory (CD-ROM), etc. The input/output device 2040 may include an input device, such as a keyboard, a mouse, a keypad, etc., and an output device, such as a printer, a display device, etc. The power supply 2050 may supply power to the computing device 2000.

The camera 2060 may be coupled to the processor 2010 via the buses or other communication links. The camera 2060 may employ one of the camera 800a of FIG. 19, the camera 800b of FIG. 20, the camera 1000 of FIG. 21 and the camera 1020 of FIG. 30. The camera 2060 and the processor 2010 may be integrated in one chip, or may be implemented as separate chips.

In some embodiments, camera 2060 and/or components of the camera 2060 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

The computing system 2000 may be any computing system including the camera 2060. For example, the computing system 2000 may include a digital camera, a mobile phone, a smart phone, a personal digital assistants (PDA), a portable multimedia player (PMP), etc.

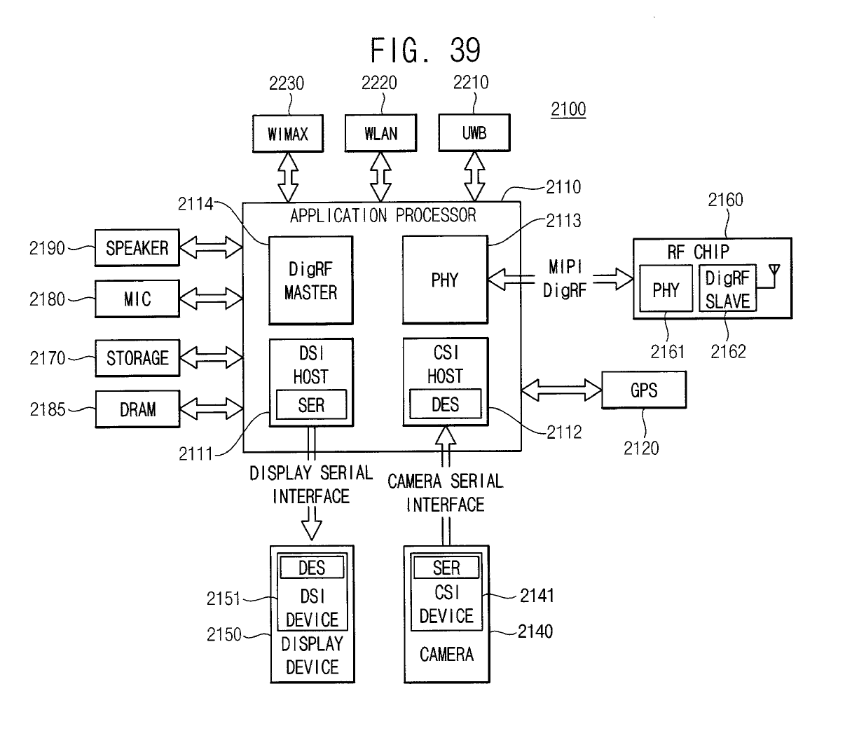

FIG. 39 is a block diagram illustrating an example of an interface used in a computing system of FIG. 38.

Referring to FIG. 39, a computing system 2100 may employ or support a MIPI interface, and may include an application processor 2110, a camera 2140 and a display device 2150. A CSI host 2112 of the application processor 2110 may perform a serial communication with a CSI device 2141 of the camera 2140 using a camera serial interface (CSI). In some embodiments, the CSI host 2112 may include a deserializer DES, and the CSI device 2141 may include a serializer SER. A DSI host 2111 of the application processor 2110 may perform a serial communication with a DSI device 2151 of the display device 2150 using a display serial interface (DSI). In some embodiments, the DSI host 2111 may include a serializer SER, and the DSI device 2151 may include a deserializer DES.

The computing system 2100 may further include a radio frequency (RF) chip 2160. A physical interface (PHY) 2113 of the application processor 2110 may perform data transfer with a PHY 2161 of the RF chip 2160 using a MIPI DigRF. The PHY 2113 of the application processor 2110 may include a DigRF MASTER 2114 for controlling the data transfer with the PHY 2161 of the RF chip 2160. The computing system 2100 may further include a global positioning system (GPS) 2120, a storage device 2170, a microphone 2180, a DRAM 2185 and a speaker 2190. The computing system 2100 may communicate with external devices using an ultra wideband (UWB) communication 2210, a wireless local area network (WLAN) communication 2220, a worldwide interoperability for microwave access (WIMAX) communication 2230, etc. The inventive concepts may not be limited to configurations or interfaces of the computing systems 2000 and 2100 illustrated in FIGS. 38 and 39.

The inventive concept may be applied to any three-dimensional image sensor or any system including the three-dimensional image sensor, such as a computer, a digital camera, a three-dimensional camera, a mobile phone, a personal digital assistant (PDA), a scanner, a navigator, a video phone, a monitoring system, an auto focus system, a tracking system, a motion capture system, an image stabilizing system, etc.

While example embodiments have been particularly shown and described, it will be understood by those of ordinary skill in the art that various changes in form and details may be made therein without departing from the spirit and scope of the present invention as defined by the following claims.

What is claimed is:

1. A three-dimensional image sensor, comprising:
a light source module configured to emit at least one light to an object;
a sensing circuit configured to polarize a received light that represents the at least one light reflected from the object and configured to convert the polarized light to electrical signals; and
a control unit configured to control the light source module and the sensing circuit.

2. The three-dimensional image sensor of claim 1, wherein the light source module comprises:
a light source configured to generate the at least one light; and
a first lens configured to focus the at least one light on the object.

3. The three-dimensional image sensor of claim 2, wherein the sensing circuit comprises a lens module and a sensor unit,
wherein the lens module comprises:
a second lens configured to concentrate the received light;
an infrared filter configured to filter visible light components in the received light; and
a polarization filter configured to polarize an output of the infrared filter in one direction to provide the polarized light; and
wherein the sensor unit is configured to convert the polarized light to the electrical signals.

4. The three-dimensional image sensor of claim 2, wherein the light source includes a light-emitting diode or a laser diode.

5. The three-dimensional image sensor of claim 2, wherein the sensing circuit comprises a lens module and a sensor unit, and
wherein the lens module comprises:
a second lens configured to concentrate the received light; and
an infrared filter configured to filter visible light components in the received light.

6. The three-dimensional image sensor of claim 5, wherein the sensor unit comprises a plurality of unit pixels, each of the unit pixels including a grid polarizer,
wherein each of the unit pixels comprises:
a transmission gate formed over a semiconductor substrate;
a floating diffusion region formed over the semiconductor substrate adjacent to the transmission gate;
a buried channel formed in the semiconductor substrate adjacent to the transmission gate;
a pinning layer formed in the buried channel; and
a metal layer formed over the transmission gate and the buried channel; and
wherein the grid polarizer is configured to polarize an output of the infrared filter, and
wherein the grid polarizer includes the buried channel and the metal layer.

7. The three-dimensional image sensor of claim 1, wherein the at least one light includes first and second lights, and
wherein the light source module comprises:
a first light source configured to emit the first light; and
a second light source configured to emit the second light; and
wherein the sensing circuit comprises a lens configured to concentrate the received light.

8. The three-dimensional image sensor of claim 7, wherein the first and second light sources are opposed to each other with respect to the lens.

9. The three-dimensional image sensor of claim 8, wherein the first and second lights have a same period with respect to each other, and
wherein the control unit provides first and second control signals that alternately enable the first and second light sources.

10. A camera, comprising:
a receiving lens;
a sensor module configured to generate depth data, the depth data including depth information of a plurality of objects based on a received light from the objects;
an engine unit configured to generate a depth map of the objects based on the depth data, configured to segment the objects in the depth map based on the depth map, and configured to generate a control signal for controlling the receiving lens based on the segmented objects; and
a motor unit configured to control focusing of the receiving lens based on the control signal;
wherein the sensor module is configured to generate color data of the objects based on visible light reflected from the objects and concentrated by the receiving lens, and
wherein the motor unit is configured to control focusing of the receiving lens to provide the color data to the engine unit.

11. The camera of claim 10, wherein the sensor module comprises:
a depth sensor configured to generate the depth data; and
a color sensor configured to generate the color data.

12. The camera of claim 10, wherein the engine unit comprises:
a first image signal processor (ISP) configured to process the depth data to generate a depth image of the objects and the depth map;
a segmentation and control unit configured to segment the objects based on the depth map, and configured to generate the control signal based on the segmented objects; and
a second ISP configured to process the color data to generate a color image of the objects.

13. The camera of claim 12, wherein the second ISP is configured to perform color image processing on each of the objects according to respective distances of the objects from the sensor module.

14. The camera of claim 10, wherein the receiving lens is configured to have a depth of field that covers one of the objects.

15. The camera of claim 12, further comprising:
an image generator;
wherein the image generator is configured to execute an application to generate a stereo image of the objects based on the depth image and the color image.

16. An imaging system, comprising:
a receiving lens;
a sensor module configured to generate color data and depth data, the color data including color information of one or more objects based on received light from the one or more objects, and the depth data including depth information of the one or more objects based on the received light from the objects;
an engine unit configured to generate a color image of the one or more objects based on the color data, configured to generate a depth image of the one or more objects based on the depth data, configured to generate a depth map of the one or more objects based on the depth data, and configured to generate a control signal for controlling the receiving lens based on the depth map; and
a motor unit configured to control focusing of the receiving lens based on the control signal.

17. The imaging system of claim 16, wherein the sensor module is further configured to generate the color data based on visible light reflected from the one or more objects and concentrated by the receiving lens.

18. The imaging system of claim 16, wherein the sensor module is further configured to generate the depth data based on infrared or near-infrared light reflected from the one or more objects and concentrated by the receiving lens.

19. The imaging system of claim 16, wherein the sensor module is further configured to polarize light reflected from the one or more objects.

20. The imaging system of claim 19, wherein the sensor module is further configured to convert the polarized light to electrical signals.
